(19) United States
(12) Patent Application Publication
(10) Pub. No.: US 2026/0101729 A1
(43) Pub. Date: Apr. 9, 2026

(54) SEMICONDUCTOR DEVICE WITH ISOLATION STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: KO MAI, KAOHSIUNG CITY (TW); MENG CHI HANG, HSINCHU CITY (TW); CHIEN-LIN TSENG, HSINCHU COUNTY (TW); CHUNG-CHUAN TSENG, HSINCHU CITY (TW)

(21) Appl. No.: 18/910,022

(22) Filed: Oct. 9, 2024

(51) Int. Cl. H01L 21/762; H01L 21/265; H01L 21/306; H01L 21/3065; H01L 27/12

(52) U.S. Cl. CPC H10P 90/1906; H10D 86/201; H10P 30/20; H10P 50/242; H10P 50/642; H10W 10/014; H10W 10/061; H10W 10/17; H10W 10/181

(57) ABSTRACT

A semiconductor device is provided. A semiconductor device includes a first semiconductive region, a second semiconductive region, an isolation structure and at least one inner via. The isolation structure is formed between the first semiconductive region and the second semiconductive region and includes an isolation bottom formed beneath the second semiconductive region; and an isolation ring having a lower portion connecting the isolation bottom and an upper portion surrounding the second semiconductive region. The at least one inner via is formed in the second semiconductive region, on the isolation bottom and surrounded by the isolation structure. The isolation structure and the least one inner via have insulating materials.

### BACKGROUND

Semiconductor devices are used in a large number of electronic devices, such as computers, cell phones, and others. Semiconductor devices comprise integrated circuits that are formed on semiconductor wafers by depositing many types of thin films of material over the semiconductor wafers, and patterning the thin films of material to form the integrated circuits. Integrated circuits include field-effect transistors (FETs) such as metal oxide semiconductor (MOS) transistors.

One of the goals of the semiconductor industry is to continue shrinking the size and increasing the speed of individual FETs. Silicon on insulator (SOI) devices have been recognized as one of the possible solutions to enable continued scaling. SOI devices offer a number of advantages over bulk devices. For example, SOI devices exhibit very low junction capacitance compared to bulk devices. The source and drain junction capacitances are almost entirely eliminated.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor device, in accordance with some embodiments of the present disclosure.

FIG. 2 illustrates a cross-sectional side view, which is along line A-A of the semiconductor device shown in FIG. 1, in accordance with some embodiments of the present disclosure.

FIG. 3 illustrates a top view of the semiconductor device shown in FIG. 1, in accordance with some embodiments of the present disclosure.

FIGS. 4A to 4K illustrate top views of the semiconductor device in accordance with various embodiments of the present disclosure.

FIGS. 5A to 5H illustrate top views of the semiconductor device in accordance with various embodiments of the present disclosure.

FIGS. 6 and 7 illustrate top views of the semiconductor device in accordance with various embodiments of the present disclosure.

FIGS. 8A to 8C illustrate cross-sectional side views of the semiconductor device, in accordance with various embodiments of the present disclosure.

FIG. 9 is a flowchart of a method for forming the semiconductor device in accordance with some embodiments.

FIGS. 10A to 10F illustrate various perspective views of forming the semiconductor device in accordance with some embodiments as described in FIG. 9.

FIGS. 11A to 11D illustrate various cross-sectional side views along line C-C of the semiconductor device shown in FIGS. 10A to 10C and 10F, respectively, in accordance with some embodiments of the present disclosure.

FIGS. 12A to 12C illustrate cross-sectional side views along line D-D of the semiconductor device shown in FIGS. 10D-10F, respectively, in accordance with some embodiments of the present disclosure.

FIG. 13 illustrates a schematic diagram showing a dopant concentration in an embedded doped region and neighboring area in a substrate of the semiconductor device in accordance with some embodiments of the present disclosure.

FIG. 14 illustrates a top cross-sectional view of the semiconductor device shown in FIG. 10D, in accordance with some embodiments of the present disclosure.

FIG. 15 illustrates a top view of the semiconductor device shown in FIG. 10F, in accordance with some embodiments of the present disclosure.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A comparative semiconductor-on-insulator (SOI) structure comprises a substrate, an insulator formed on the substrate and a layer of semiconductive material formed on the insulator, so that the insulator isolates the layer of semiconductive material from the substrate. However, such insulator can only provide a single-direction isolation and require high costs. Alternatively, anti-doped implantation may be conducted to provide a full direction junction isolation. However, such junction isolation may bring parasitic capacitance and would reduce device performance. Furthermore, the isolation ability of the junction isolation may be worse than that of the insulator. There is a need to provide a cost effective isolation structure with superior full direction isolation and less parasitic effect.

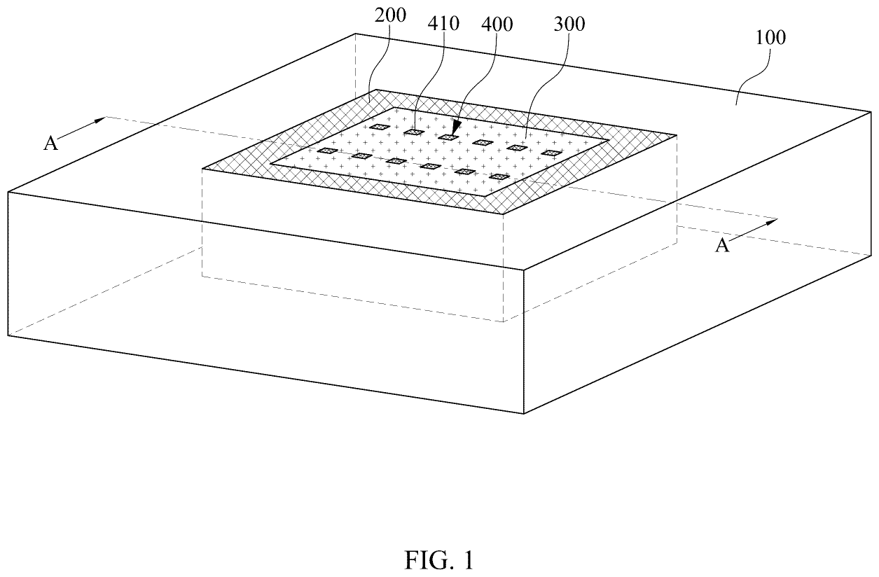

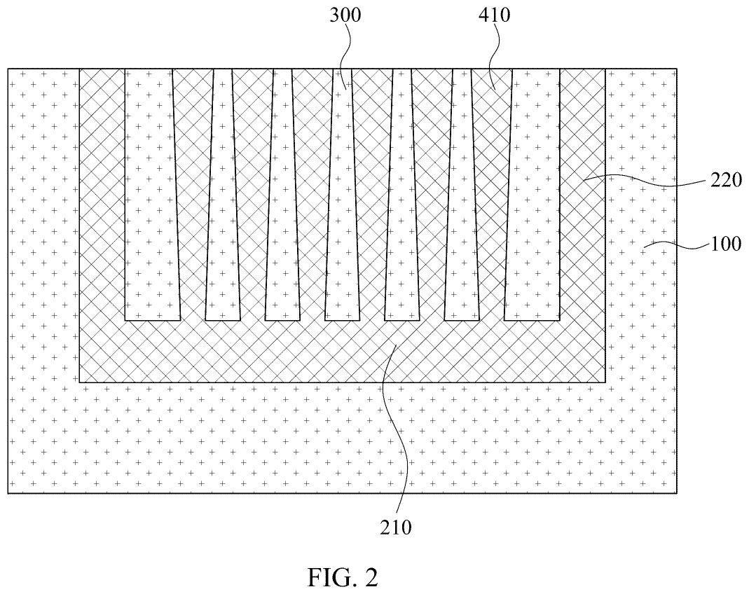

Referring to FIGS. 1 and 2, the semiconductor device includes a first semiconductive region 100, an isolation structure 200, a second semiconductive region 300 and a via array 400.

The first semiconductive region 100 may be formed in the semiconductor device using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof. In some embodiments, the first semiconductive region 100 comprises SiGe, Ge, GeSn, SiGeSn, or a III-V material. In embodiments wherein the first semiconductive region 100 comprises a III-V material, the first semiconductive region 100 may comprise InAs, AlAs, GaAs, InP, GaN, InGaAs, InAlAs, GaSb, AlSb, AlP, or GaP, as examples. The first semiconductive region 100 may comprise a thickness of about 3 nm to about 30 nm, or about 10 nm to about 20 nm, for example. The first semiconductive region 100 may also comprise other materials and dimensions, and may be formed using other methods.

The isolation structure 200 is formed in the first semiconductive region 100 and has an isolation bottom 210 and an isolation ring 220. A top of the isolation structure 200 may be substantially coplanar with a top of the first semiconductive region 100. The isolation bottom 210 is formed in the first semiconductive region 100 and may comprise oxide (such as SiO, doped SiO and so on), nitride (such as SiN), carbide (such as SiC), low k materials or a combination thereof. For example, the isolation bottom 210 may comprise silicon oxide, doped silicon oxide, silicon carbide, silicon nitride and so on. These are, of course, merely examples and are not intended to be limiting.

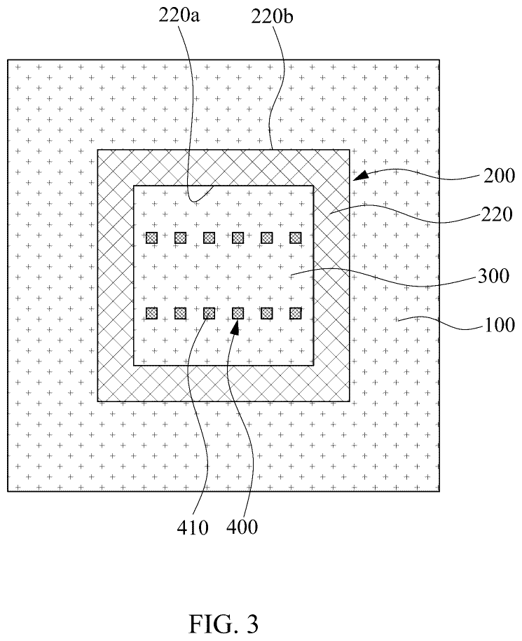

The isolation ring 220 has a lower portion connecting the isolation bottom 210 and an upper portion surrounding the second semiconductive region 300. The isolation ring 220 may be in any shape, such as a rectangular shape (as shown in FIG. 3), a triangular shape, circular shape, or other regular or irregular shapes. These are, of course, merely examples and are not intended to be limiting.

As shown in FIG. 3, an inner surface 220a of the isolation ring 220 may be a substantially flat surface and an outer surface 220b of the isolation ring 220 may be a substantially flat surface.

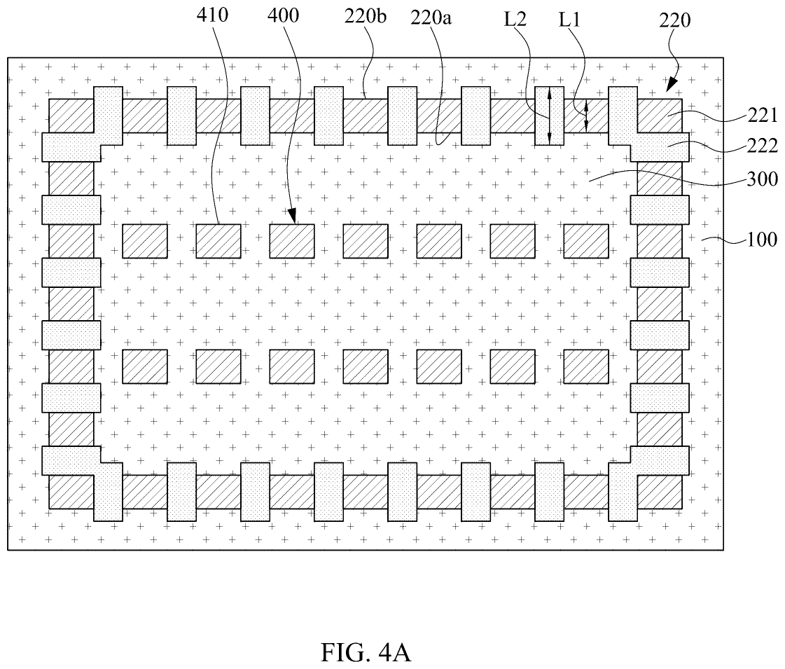

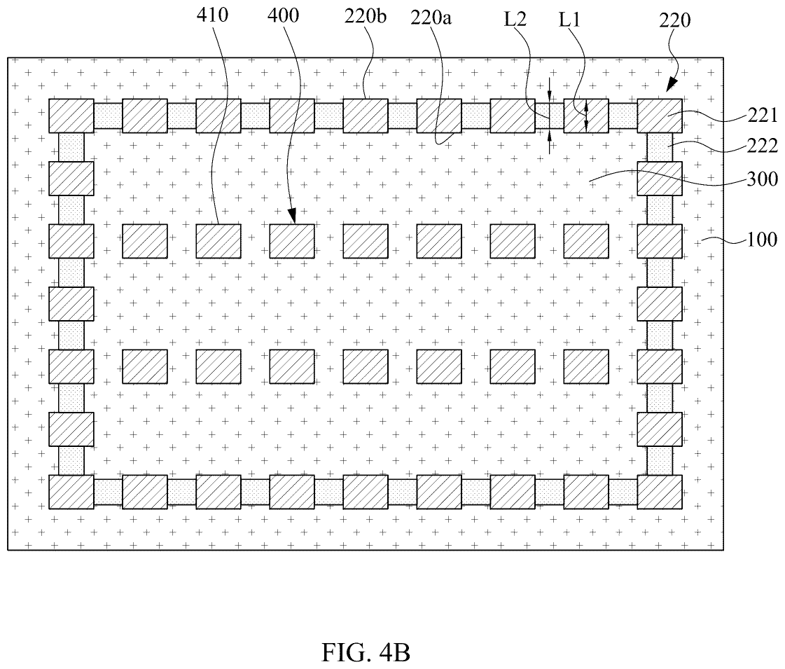

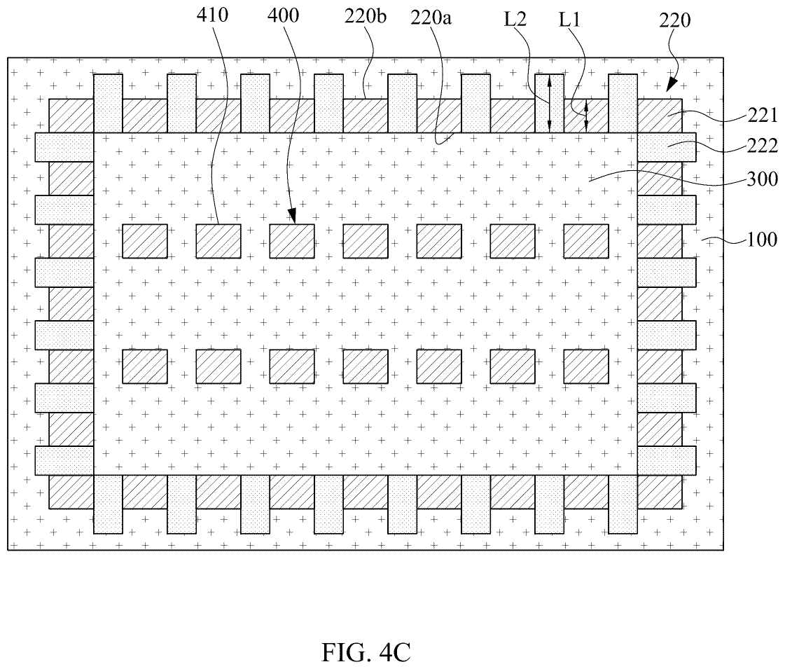

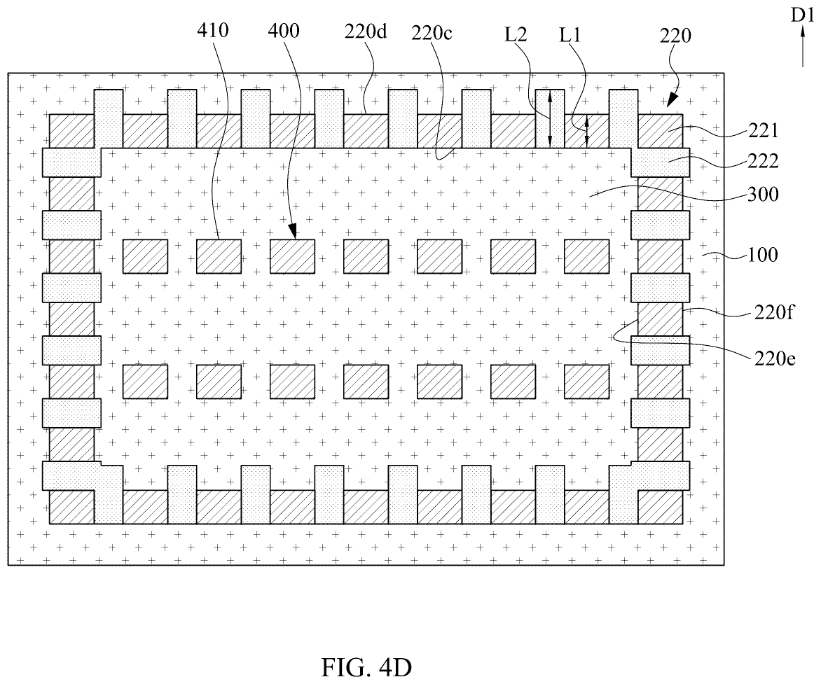

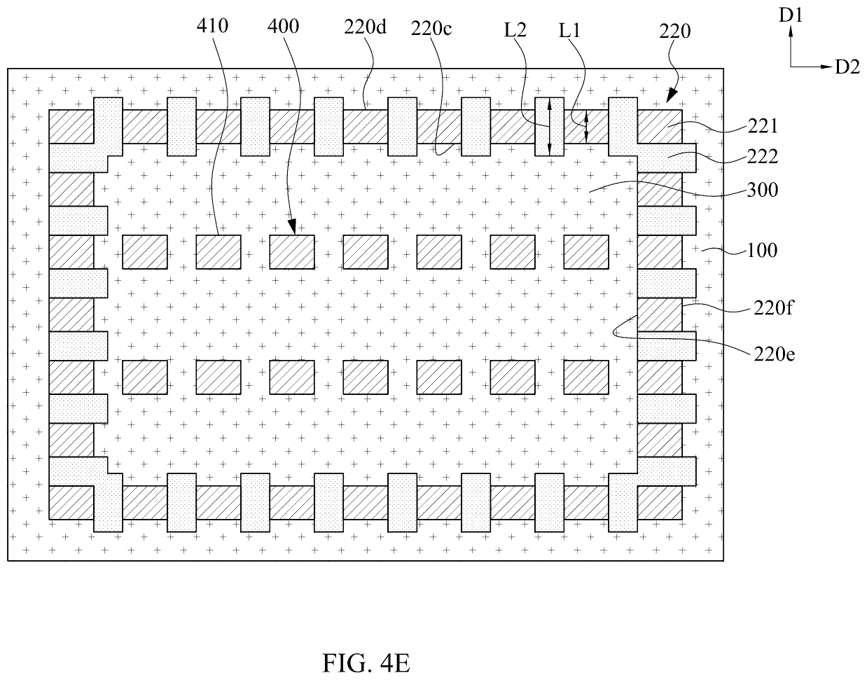

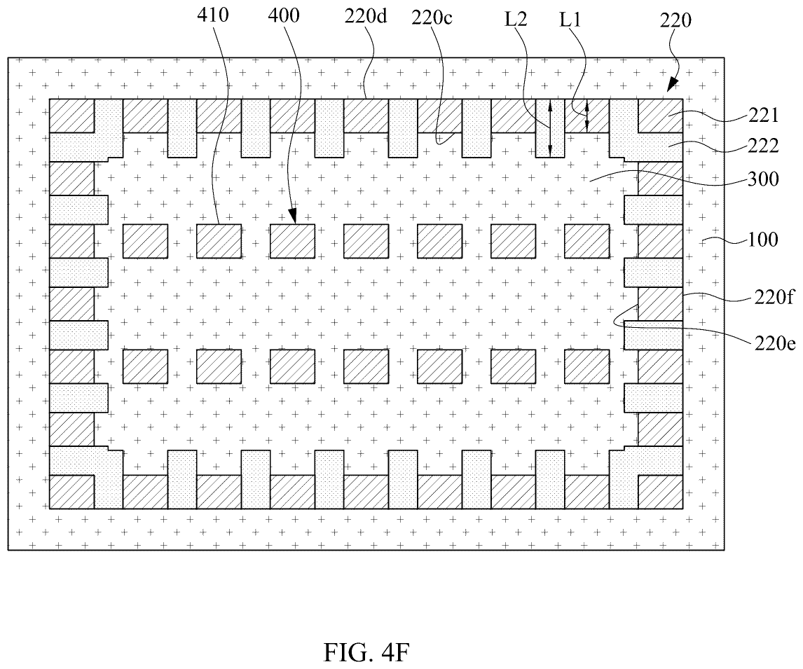

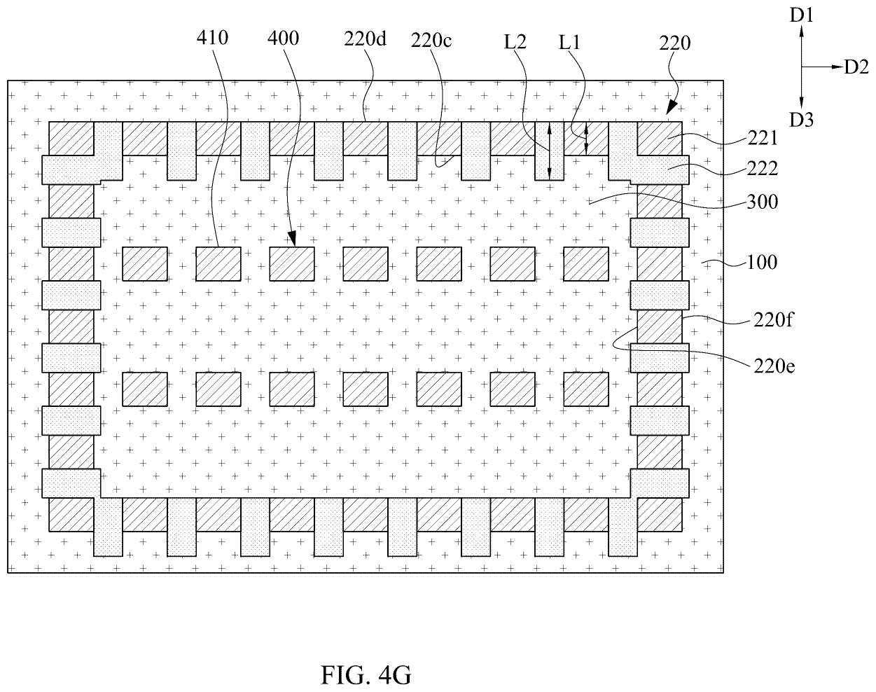

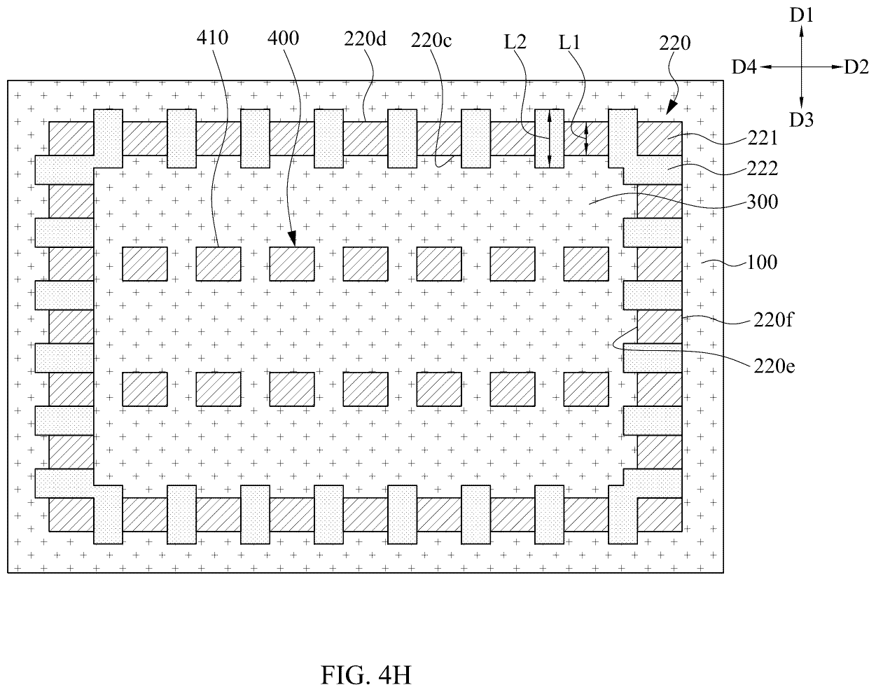

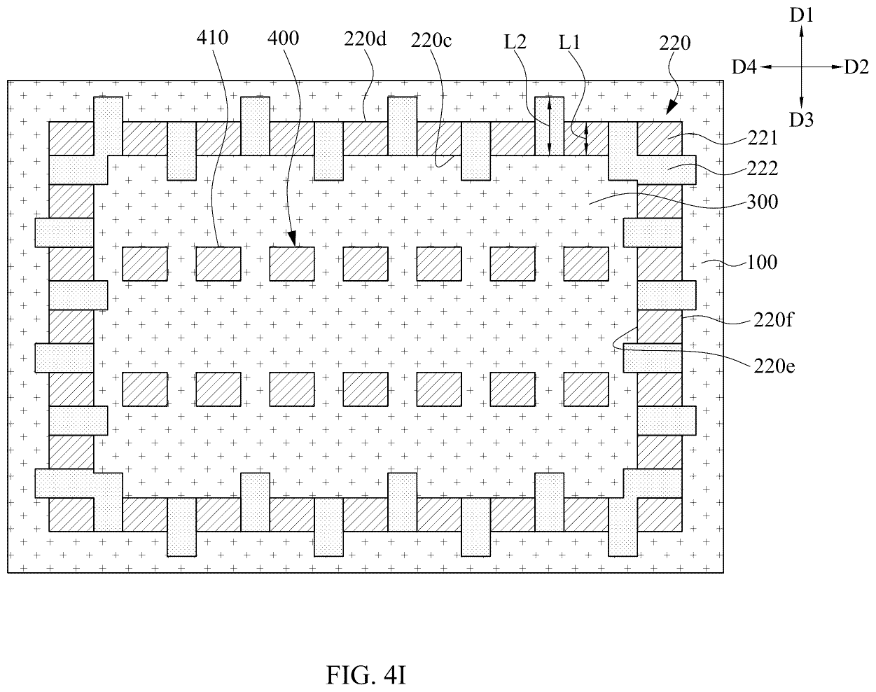

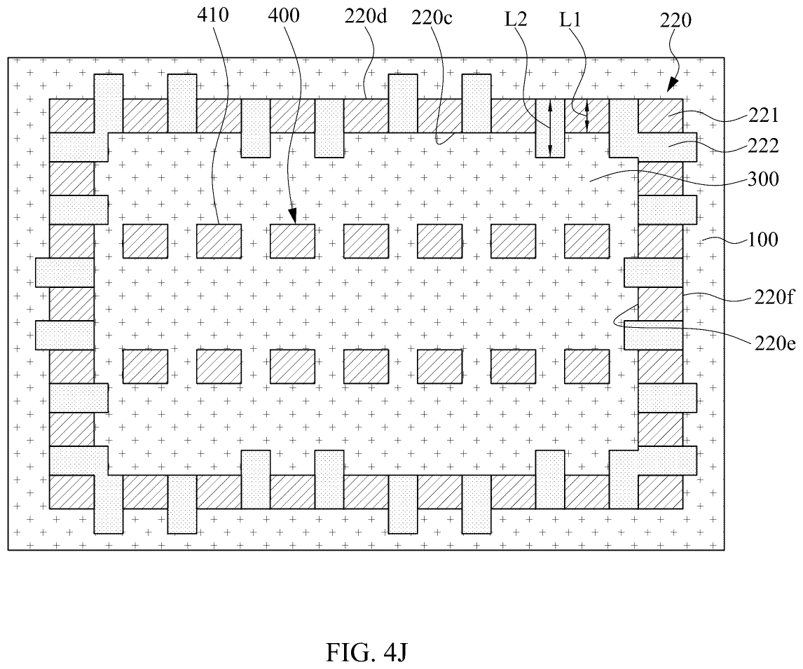

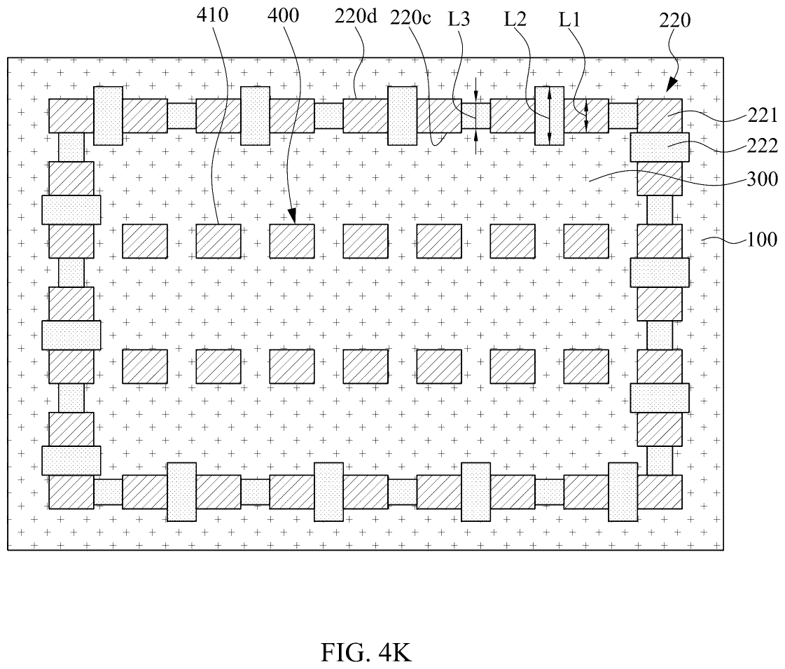

As shown in FIGS. 4A to 4J, the isolation ring 220 is a rectangular ring, which may comprise a plurality of first insulating vias 221 and a plurality of second insulating vias 222 formed alternately. The first insulating via 221 has a length L1 and the second insulating via 222 has a length L2.

As shown in FIG. 4A, in some embodiments, the length L1 of the first insulating via 221 is less than the length L2 of the second insulating via 222, and the second insulating via 222 has an outer surface expanding toward the first semiconductive region 100, and an inner surface expanding toward the second semiconductive region 300. Therefore, the inner surface 220a of the isolation ring 220 can be a serrated surface and the outer surface 220b of the isolation ring 220 can be a serrated surface. Since the outer surface and the inner surface of each of the second insulating vias 222 are expanding, some of the second insulating vias 222 may overlap to some extent. For example, some of the second insulating vias 222 at corners of the isolation ring 220 as shown in FIG. 4A.

As shown in FIG. 4B, in some embodiments, the length L1 of the first insulating via 221 is greater than the length L2 of the second insulating via 222; and the second insulating via 222 has an outer surface retracted toward the second semiconductive region 300 and an inner surface retracted toward the first semiconductive region 100. Therefore, the inner surface 220a of the isolation ring 220 can be a serrated surface and the outer surface 220b of the isolation ring 220 can be a serrated surface.

As shown in FIG. 4C, in some embodiments, the length L1 of the first insulating via 221 is less than the length L2 of the second insulating via 222; and the second insulating via 222 has an outer surface expanding toward the first semiconductive region 100 and an inner surface aligned with an inner surface of the first insulating via 221. Therefore, the inner surface 220a of the isolation ring 220 can be a substantially flat surface and the outer surface 220b of the isolation ring 220 can be a serrated surface.

As shown in FIG. 4D, in some embodiments, the length L1 of the first insulating via 221 is less than the length L2 of the second insulating via 222. The isolation ring 220 is a rectangular ring including two long sides and two short sides. The second insulating via 222 on the long side of the isolation ring 220 has an outer surface expanding toward the first semiconductive region 100 and an inner surface aligned with an inner surface of the first insulating via 221 on the long side of the isolation ring 220, so the inner surface 220c on the long side of the isolation ring 220 is a substantially flat surface while the outer surface 220d on the long side of the isolation ring 220 is a serrated surface. That is, based on FIG. 4A, all the second insulating via 222 on the long side of the isolation ring 220 are shifted in a first direction D1. The second insulating via 222 on the short side of the isolation ring 220 has an outer surface expanding toward the first semiconductive region 100 and an inner surface expanding toward the second semiconductive region 300, so the inner surface 220e on the short side of the isolation ring 220 is a serrated surface while the outer surface 220f on the short side of the isolation ring 220 is a serrated surface.

As shown in FIG. 4E, in some embodiments, the length L1 of the first insulating via 221 is less than the length L2 of the second insulating via 222. The isolation ring 220 is a rectangular ring including two long sides and two short sides. The second insulating via 222 on the long side of the isolation ring 220 has an outer surface expanding toward the first semiconductive region 100 and an inner surface expanding toward the second semiconductive region 300, so the inner surface 220c on the long side of the isolation ring 220 is a serrated surface while the outer surface 220d on the long side of the isolation ring 220 is a serrated surface. The second insulating via 222 on the short side of the isolation ring 220 has an outer surface expanding toward the first semiconductive region 100 and an inner surface aligned with an inner surface of the first insulating via 221 on the short side of the isolation ring 220. That is, based on FIG. 4A, all the second insulating via 222 on the short side of the isolation ring 220 are shifted in a second direction D2 perpendicular to the first direction D1.

As shown in FIG. 4F, in some embodiments, the length L1 of the first insulating via 221 is less than the length L2 of the second insulating via 222. The isolation ring 220 is a rectangular ring including two long sides and two short sides. The second insulating via 222 on the long side of the isolation ring 220 has an outer surface aligned with an outer surface of the first insulating via 221 on the long side of the isolation ring 220 and an inner surface expanding toward the second semiconductive region 300, so the inner surface 220c on the long side of the isolation ring 220 is a serrated surface while the outer surface 220d on the long side of the isolation ring 220 is a substantially flat surface. The second insulating via 222 on the short side of the isolation ring 220 has an outer surface aligned with an outer surface of the first insulating via 221 on the short side of the isolation ring 220 and an inner surface expanding toward the second semiconductive region 300, so the inner surface 220e on the short side of the isolation ring 220 is a serrated surface while the outer surface 220f on the short side of the isolation ring 220 is a substantially flat surface.

As shown in FIG. 4G, in some embodiments, the length L1 of the first insulating via 221 is less than the length L2 of the second insulating via 222. The isolation ring 220 is a rectangular ring including two long sides and two short sides. The second insulating via 222 on the long side of the isolation ring 220 has an outer surface aligned with an outer surface of the first insulating via 221 on the long side of the isolation ring 220 and an inner surface expanding toward the second semiconductive region 300, so the inner surface 220c on the long side of the isolation ring 220 is a serrated surface while the outer surface 220d on the long side of the isolation ring 220 is a substantially flat surface. That is, based on FIG. 4A, all the second insulating via 222 on the long side of the isolation ring 220 are shifted in a third direction D3 opposite to the first direction D1. The second insulating via 222 on the short side of the isolation ring 220 has an outer surface expanding toward the first semiconductive region 100 and an inner surface expanding toward the second semiconductive region 300, so the inner surface 220e on the short side of the isolation ring 220 is a serrated surface while the outer surface 220f on the short side of the isolation ring 220 is a serrated surface.

As shown in FIG. 4H, in some embodiments, the length L1 of the first insulating via 221 is less than the length L2 of the second insulating via 222. The isolation ring 220 is a rectangular ring including two long sides and two short sides. The second insulating via 222 on the long side of the isolation ring 220 has an outer surface expanding toward the first semiconductive region 100 and an inner surface expanding toward the second semiconductive region 300, so the inner surface 220c on the long side of the isolation ring 220 is a serrated surface while the outer surface 220d on the long side of the isolation ring 220 is a serrated surface. The second insulating via 222 on the short side of the isolation ring 220 has an outer surface aligned with an outer surface of the first insulating via 221 on the short side of the isolation ring 220, and an inner surface expanding toward the second semiconductive region 300, so the inner surface 220e on the short side of the isolation ring 220 is a serrated surface while the outer surface 220f on the short side of the isolation ring 220 is a substantially flat surface. That is, based on FIG. 4A, all the second insulating via 222 on the short side of the isolation ring 220 are shifted in a fourth direction D4 opposite to the second direction D2.

As shown in FIGS. 4I and 4J, in some embodiments, the length L1 of the first insulating via 221 is less than the length L2 of the second insulating via 222. Some of the second insulating via 222 have an outer surface expanding toward the first semiconductive region 100 and an inner surface aligned with an inner surface of the first insulating via 221 while the other of the second insulating via 222 have an outer surface aligned with an outer surface of the first insulating via 221 and an inner surface expanding toward the first semiconductive region 100, so the inner surface 220c of the isolation ring 220 is a serrated surface while the outer surface 220d of the isolation ring 220 is a serrated surface. As shown in FIG. 4I, based on FIG. 4A, the second insulating vias 222 on the long side are alternately shifted in the first direction D1 and the third direction D3, and the second insulating vias 222 on the short side are alternately shifted in the second direction D2 and the fourth direction D4. Referring to FIG. 4J, the shifts of the second insulating vias 222 may be modified from one-by-one to pair-to-pair.

The first insulating via 221 comprises a first insulating material and the second insulating via 222 comprises a second insulating material. The first insulating material and the second insulating material may be identical or different from each other. The first insulating material and the second insulating material may include but not limited to oxide (such as SiO, doped SiO and so on), nitride (such as SiN), carbide (such as SiC), low k materials or a combination thereof. In some embodiments, the insulating materials may comprise silicon oxide, doped silicon oxide, silicon carbide, silicon nitride and so on. These are, of course, merely examples and are not intended to be limiting. The arrangement of the first insulating via 221 and the second insulating via 222 and their dimensions can be adjusted according to required design.

As shown in FIG. 4K, in some embodiments, the isolation ring 220 may comprise a plurality of first insulating vias 221, a plurality of second insulating vias 222 and a plurality of third vias 223 formed alternately. Each of the first insulating via 221 is sandwiched between one of the plurality of second insulating vias 222 and one of the plurality of third vias 223. The first insulating via 221 has a length L1, the second insulating via 222 has a length L2 and the third via 223 has a length L3. The length L2 of the second insulating via 222 is greater than the length L1 of the first insulating via 221 and the length L3 of the third via 213; and the length L1 of the first insulating via 221 is greater than the length L3 of the third via 213. The arrangement of the first insulating via 221, the second insulating via 222 and the third via 213 and their dimensions can be adjusted according to required design. The inner surface 220a of the isolation ring 220 may be a serrated surface and the outer surface 220b of the isolation ring 220 may be a serrated surface. The first insulating via 221 comprises a first insulating material, the second insulating via 222 comprises a second insulating material and the third via 223 comprises a third insulating material. The first insulating material, the second insulating material and the third insulating material may be identical or different from each other. The first insulating material, the second insulating material and the third insulating material may include but not limited to oxide (such as SiO, doped SiO and so on), nitride (such as SiN), carbide (such as SiC), low k materials or a combination thereof. In some embodiments, the insulating materials may comprise silicon oxide, doped silicon oxide, silicon carbide, silicon nitride and so on. These are, of course, merely examples and are not intended to be limiting.

The second semiconductive region 300 is located on the isolation bottom 210 of the isolation structure 200 and is surrounded by the isolation ring 220. The second semiconductive region 300 may have a material substantially identical to the material of the first semiconductive region 100. A top of the second semiconductive region 300 is substantially coplanar with the top of the first semiconductive region 100 and the top of the isolation structure 200. An area of the top of the second semiconductive region 300 may range from about 0.1 nm² to 107 mm².

The via array 400 comprises at least one inner via 410 formed in the second semiconductive region 300 and on the isolation bottom 210. The inner vias 410 may comprise oxide (such as SiO, doped SiO and so on), nitride (such as SiN), carbide (such as SiC), low k materials or a combination thereof. For example, the isolation bottom 210 may comprise silicon oxide, doped silicon oxide, silicon carbide, silicon nitride and so on. These are, of course, merely examples and are not intended to be limiting. Materials for forming the inner vias 410 may be identical to or different from materials for forming the isolation structure 200. As shown in FIG. 2, in some embodiments, each inner via 410 has a top with an area larger than an area of a bottom of the inner via 410. In some alternative embodiments, the each inner via 410 may have a top with an area substantially identical to an area of a bottom of the inner via 410.

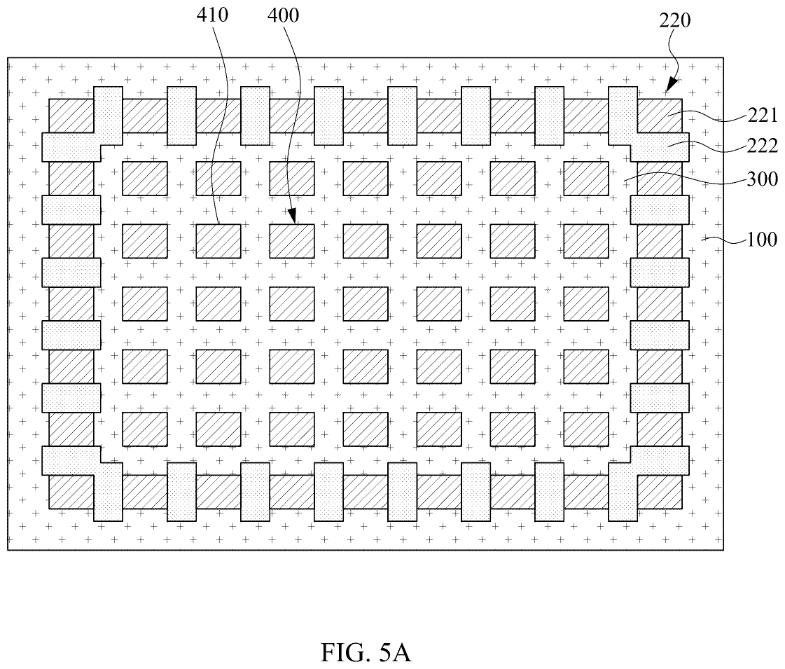

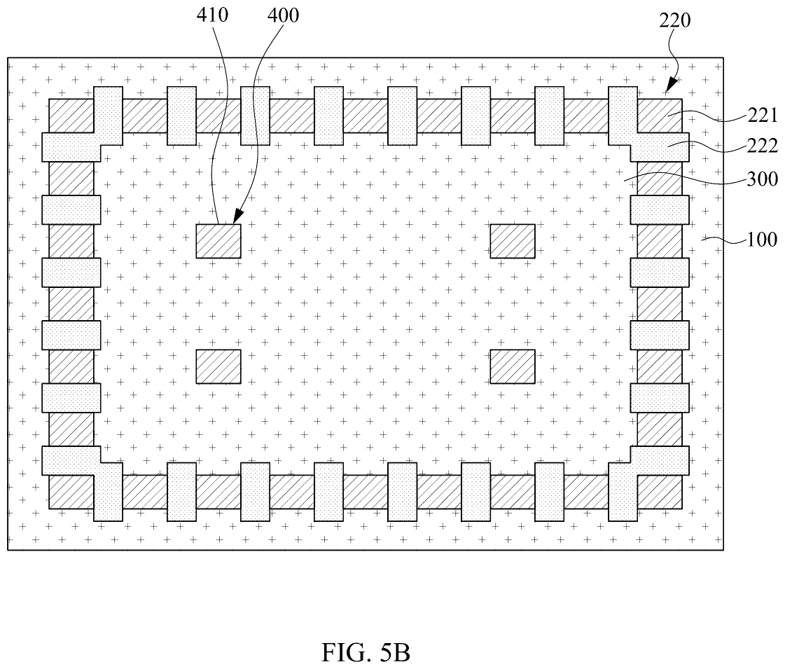

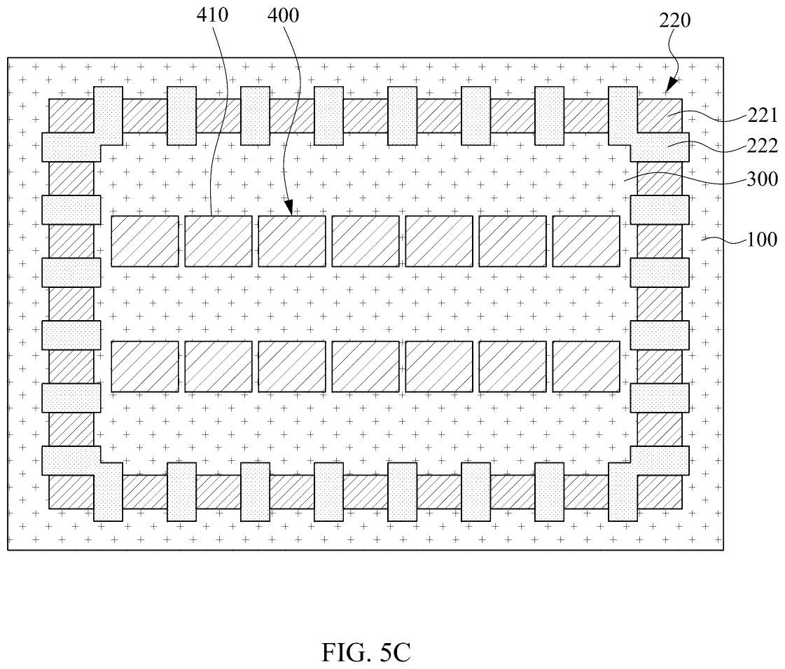

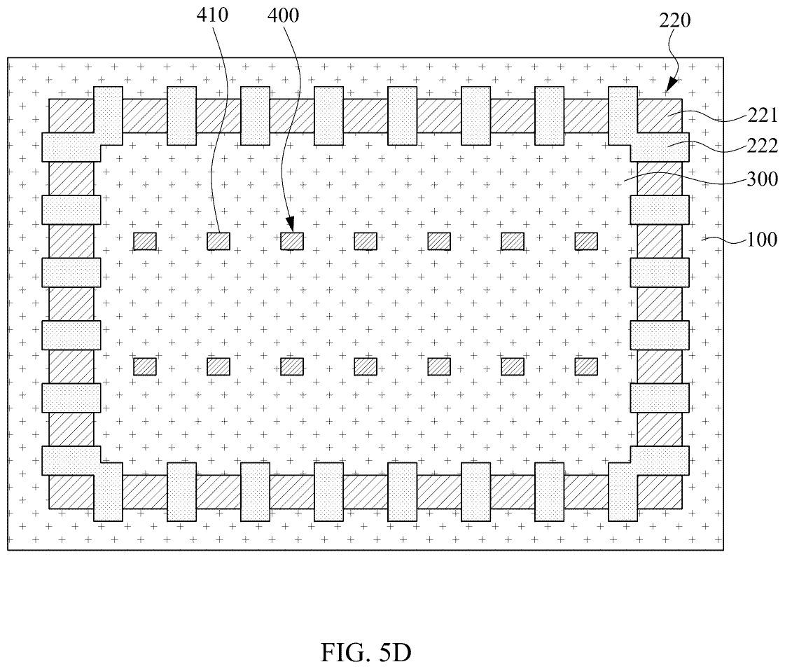

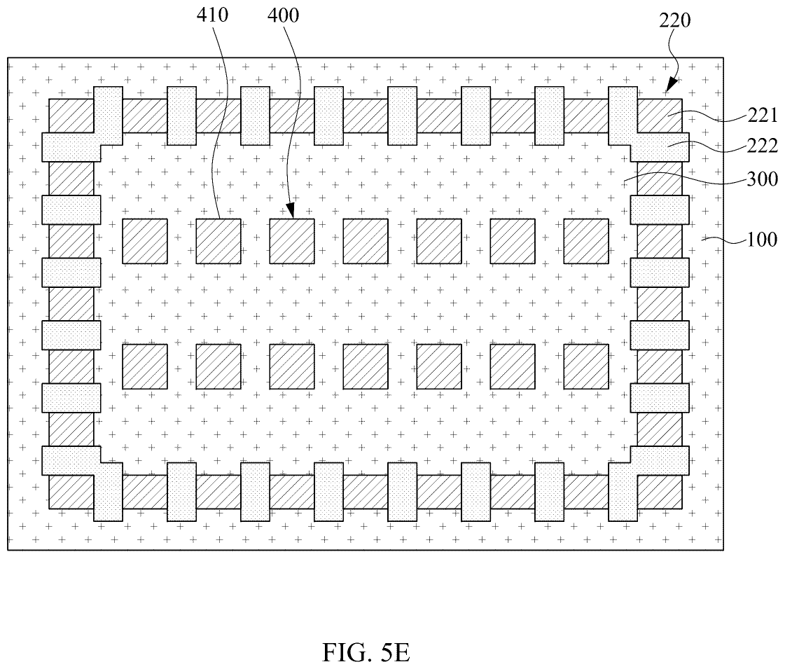

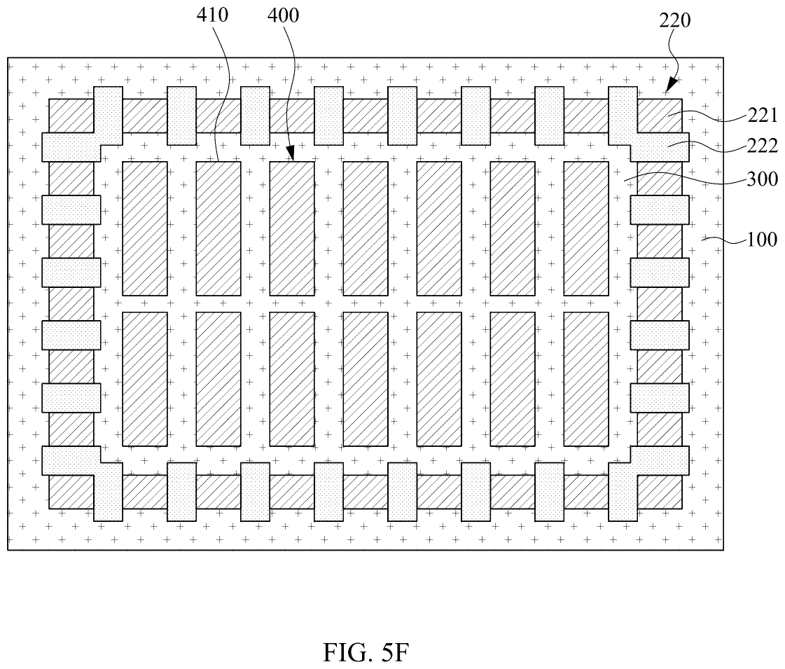

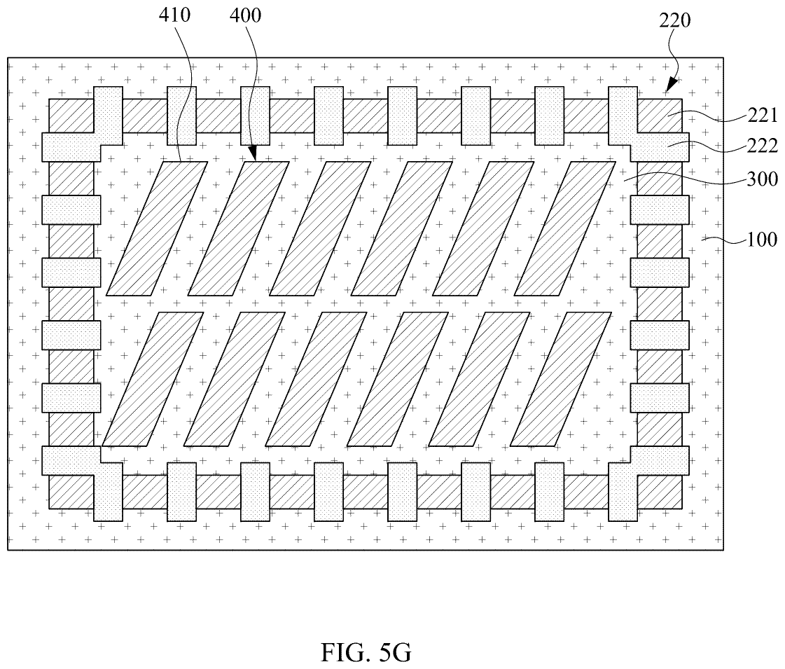

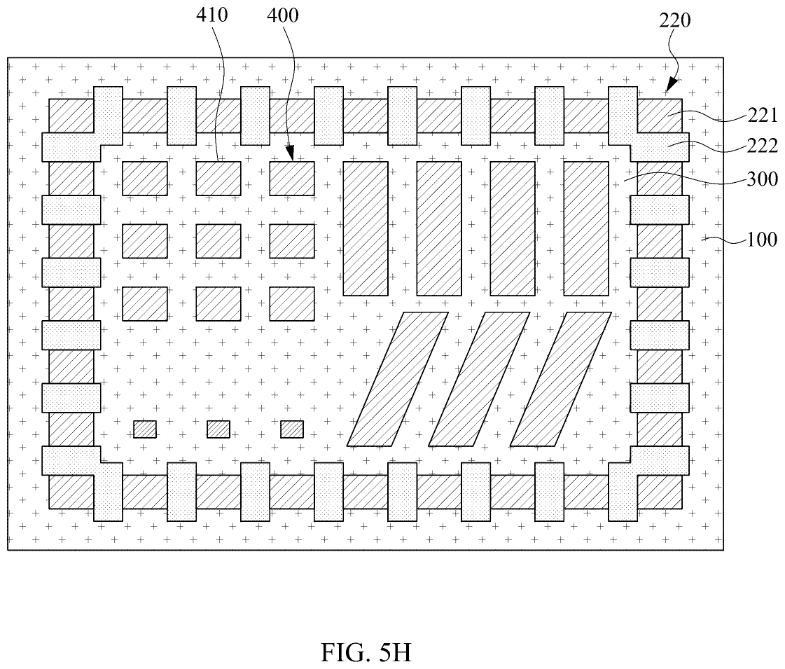

As shown in FIGS. 5A to 5H, the density of the inner vias 410 in the second semiconductive region 300 may be varied depending on the size of the second semiconductive region 300, desired performance and design and so on. For example, the via array 400 may have seven columns and five rows of inner vias 410 as shown in FIG. 5A; the via array 400 may have two columns and two rows of vias as shown in FIG. 5B. The via array 400 shown in FIGS. 5C to 5G all have seven columns and two rows of inner vias 410 and the density and dimension of the inner vias 410 can be varied. For example, each of the inner vias 410 may have a top cross section, which may have a triangular, rectangular, square, trapezoid, polygonal shape or the like. As shown in FIG. 5H, the via array 400 may have inner vias 410 with different shapes, dimensions and so on.

In some embodiments, a total area of the top surfaces of the inner vias 410 may occupy about 10% to about 90% of an area of a top surface of the second semiconductive region 300. In some embodiments, the total area of the top surfaces of the inner vias 410 may occupy about 20% to about 80% of an area of a top surface of the second semiconductive region 300. In some embodiments, the total area of the top surfaces of the inner vias 410 may occupy about 30% to about 70% of an area of a top surface of the second semiconductive region 300.

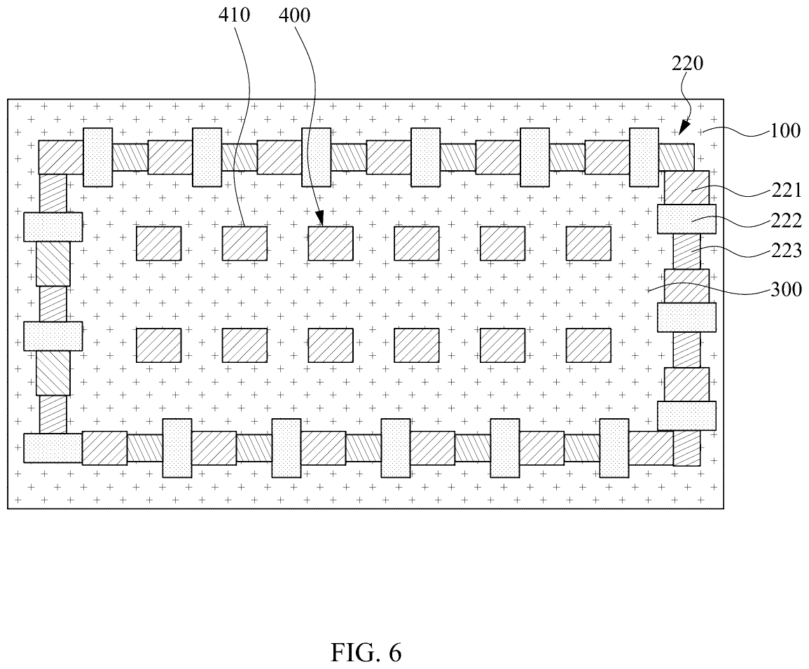

Referring to FIG. 6, in some embodiments, the isolation ring 220 may comprise a plurality of first insulating vias 221, a plurality of second insulating vias 222 and a plurality of third vias 223 formed periodically. Each of the first insulating via 221 is sandwiched between one of the plurality of second insulating vias 222 and one of the plurality of third vias 223. The first insulating via 221 comprises a first insulating material, the second insulating via 222 comprises a second insulating material and the third via 223 comprises a third insulating material. The first insulating material, the second insulating material and the third insulating material are different from each other. The inner vias 410 may have a material substantially identical to any one of the first insulating material, the second insulating material and the third insulating material or different from the first insulating material, the second insulating material and the third insulating material.

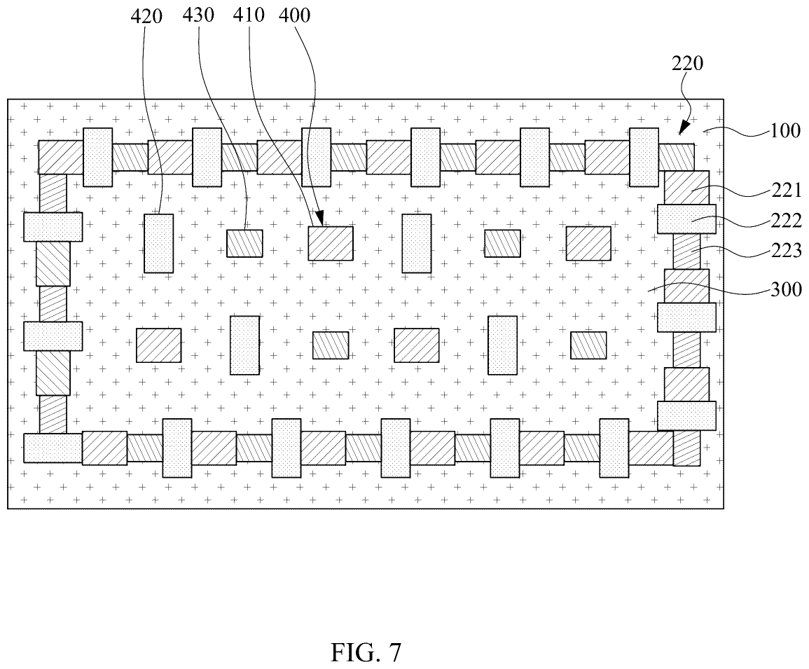

Referring to FIG. 7, in some another embodiments, the via array 400 comprises a plurality of first inner vias 410, a plurality of second inner vias 420, a plurality of third inner vias 430. The first inner vias 410, the second inner vias 420 and the third inner vias 430 may comprise identical or different materials. For example, each of the first inner vias 410, the second inner vias 420 and the third inner vias 430 may have a material substantially identical to any one of the first insulating material, the second insulating material and the third insulating material or different from the first insulating material, the second insulating material and the third insulating material to provide different insulating effects.

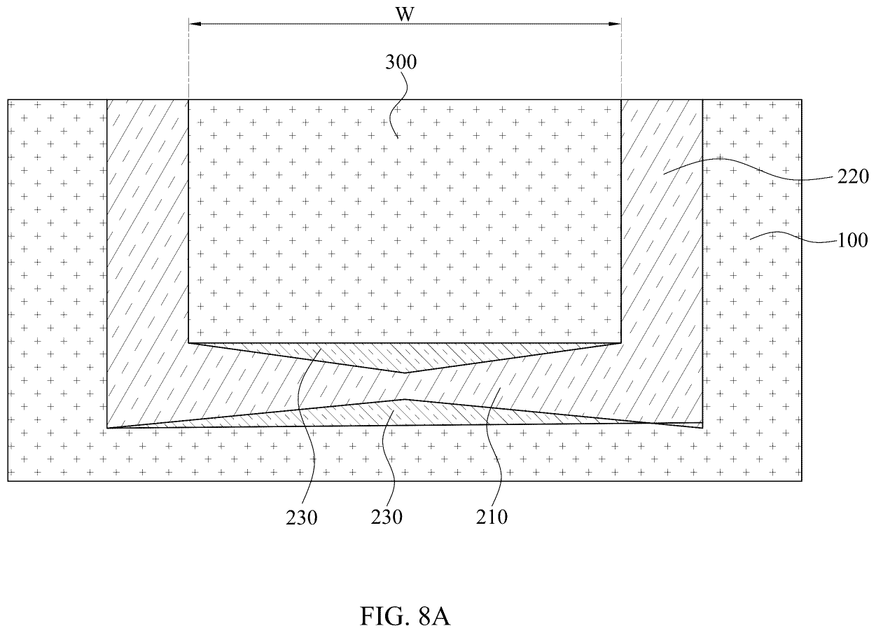

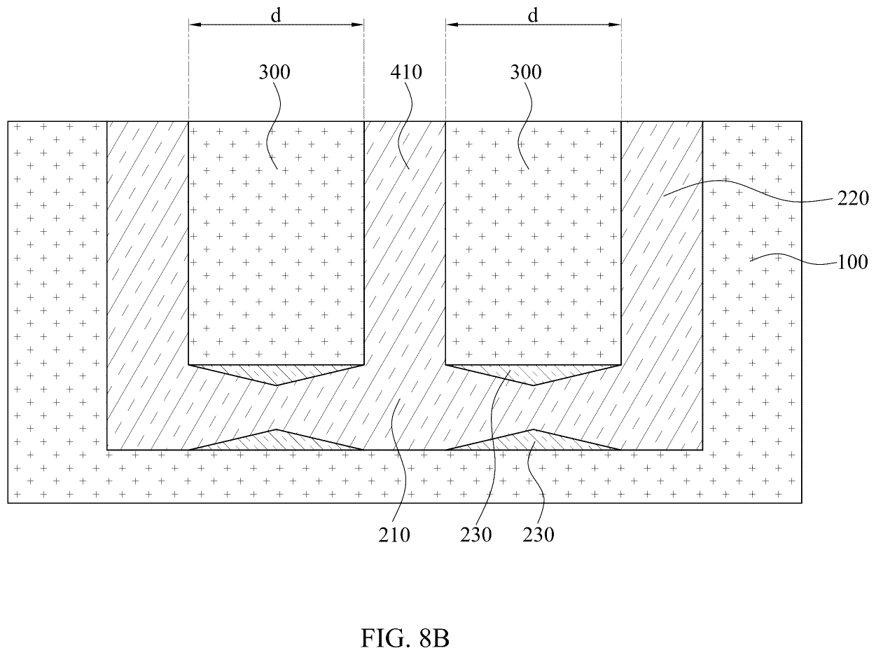

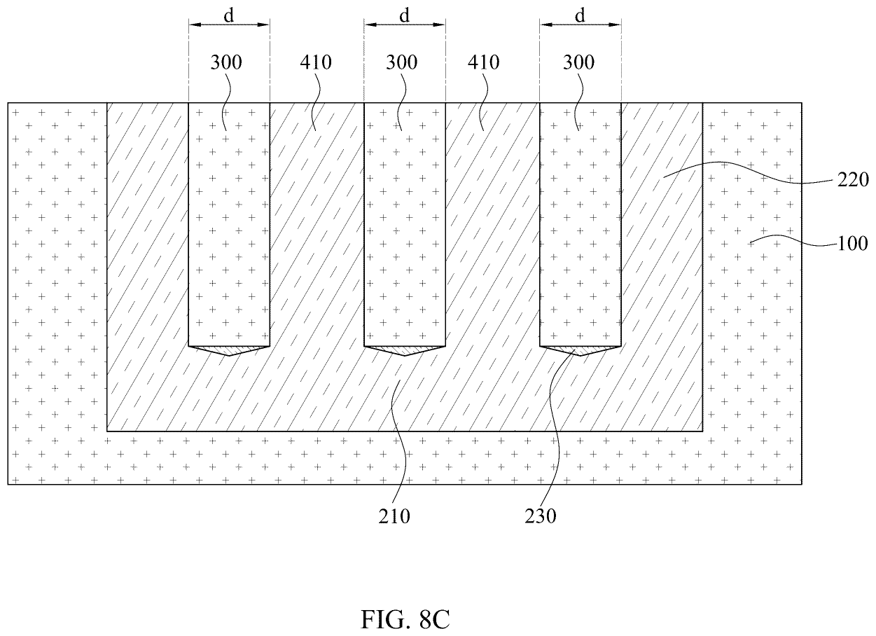

With reference to FIGS. 8A to 8C, in some embodiments, the isolation structure 200 may further comprise at least one embedded doped region 230, which can be formed on the upper surface of the isolation bottom 210 and/or formed beneath the lower surface of the isolation bottom 210. The embedded doped region 230 comprises materials with a high etching selectivity with respect to the first semiconductive region 100 and a second semiconductive region 300. For example, when the first semiconductive region 100 and the second semiconductive region 300 comprise P-type materials, the embedded doped region 230 may comprise highly doped p-type dopants (e.g., P+ dopants) or even heavily doped p-type dopants (e.g., P++ dopants). The p-type dopants may comprise B, Ga, or In implanted to a concentration equal to or greater than from about 10¹⁵ atoms/cm⁻³. In some embodiments, the concentration may range from about 10¹⁵ atoms/cm⁻³ to 10²⁰ atoms/cm⁻³. When the first semiconductive region 100 and a second semiconductive region 300 comprise n-type materials, the embedded doped region 230 may comprise highly doped n-type dopants (e.g., N+ dopants) or even heavily doped n-type dopants (e.g., N++ dopants). The n-type dopants may be phosphorus, arsenic, other n-type dopant, or combinations thereof.

The volume of the embedded doped region 230 may be varied depending on a width W of the second semiconductive region 300, a distance d between the isolation ring and the inner via 410, and a distance d2 between the inner vias (i.e., the density of the inner vias 410). As shown in FIG. 8A, as the width W of the second semiconductive region 300 is greater, the volume of the embedded doped region 230 would be higher. As shown in FIG. 8B, as the d between the isolation ring and the inner via 410 is decreased, the volume of the embedded doped region 230 would be lower. As shown in FIG. 8C, as the distance D2 between the inner vias is decreased, the volume of the embedded doped region 230 would be lower.

In some embodiments, as shown in FIG. 8C, since the density of the inner vias 410 is high, a lower surface of the isolation bottom 210 may be a substantially flat surface and an upper surface of the isolation bottom 210 may be a substantially flat surface, so that the lower surface of the isolation bottom 210 may be parallel to the upper surface of the isolation bottom 210 and a thickness of the isolation bottom 210 can be consistent. In some embodiments, as shown in FIGS. 8A and 8B, the lower surface of the isolation bottom 210 may be an irregular surface and the upper surface of the isolation bottom 210 may also be an irregular surface, so that the thickness of the isolation bottom 210 is not uniform. For example, the thickness of the isolation bottom 210 may be gradually decreased from an area near the inner vias 410 and the isolation ring 220 to an area far away from the inner vias 410 and the isolation ring 220.

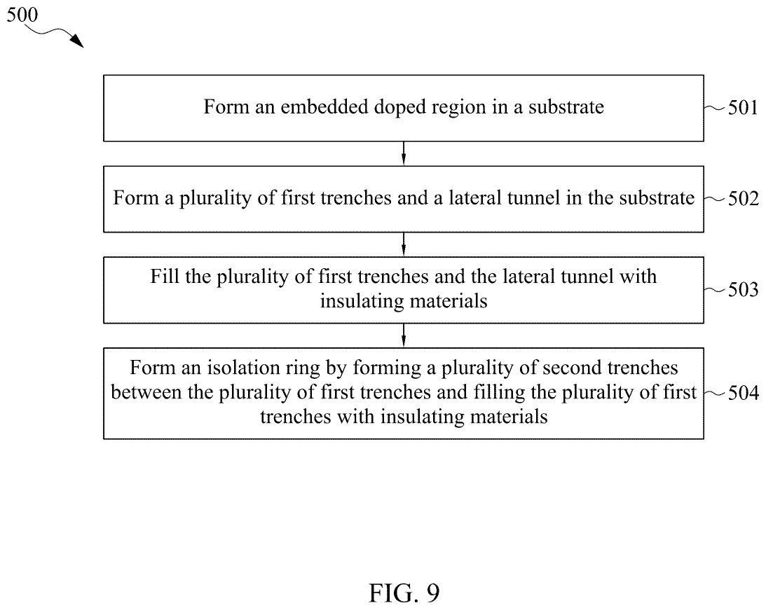

FIG. 9 is a flowchart representing a method 500 for forming a semiconductor device according to various aspects of the present disclosure. In some embodiments, the method 500 for forming the semiconductor device includes a number of operations (501, 502, 503 and 504). The method 500 for forming the semiconductor device will be further described according to one or more embodiments. It should be noted that the operations of the method 500 may be rearranged or otherwise modified within the scope of the various aspects. It should further be noted that additional processes may be provided before, during, and after the method 00, and that some other processes may be only briefly described herein. FIGS. 18A to 18E are diagrammatic perspective views illustrating various stages in the method 500 for forming the connecting structure according to aspects of one or more embodiments of the present disclosure.

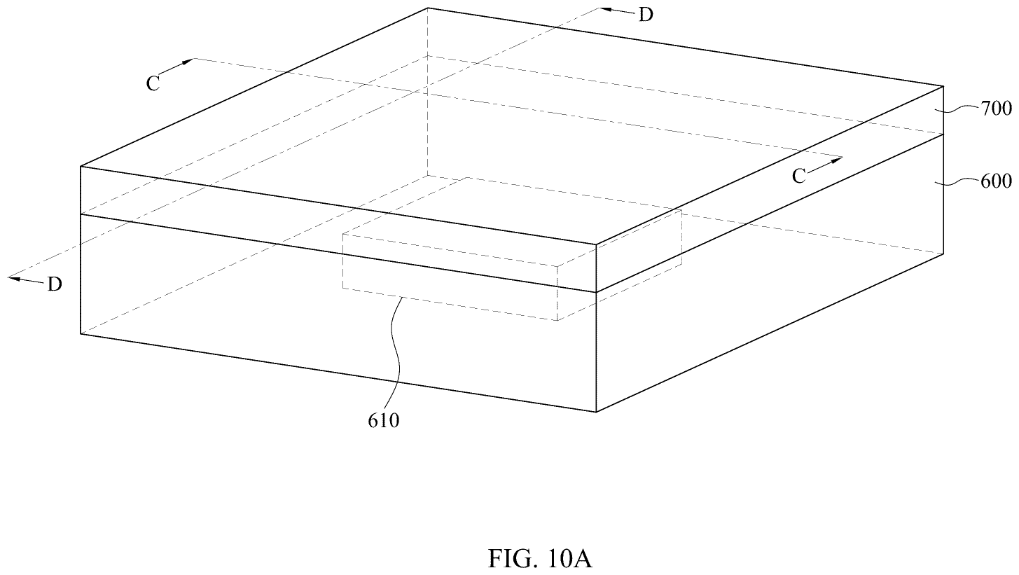

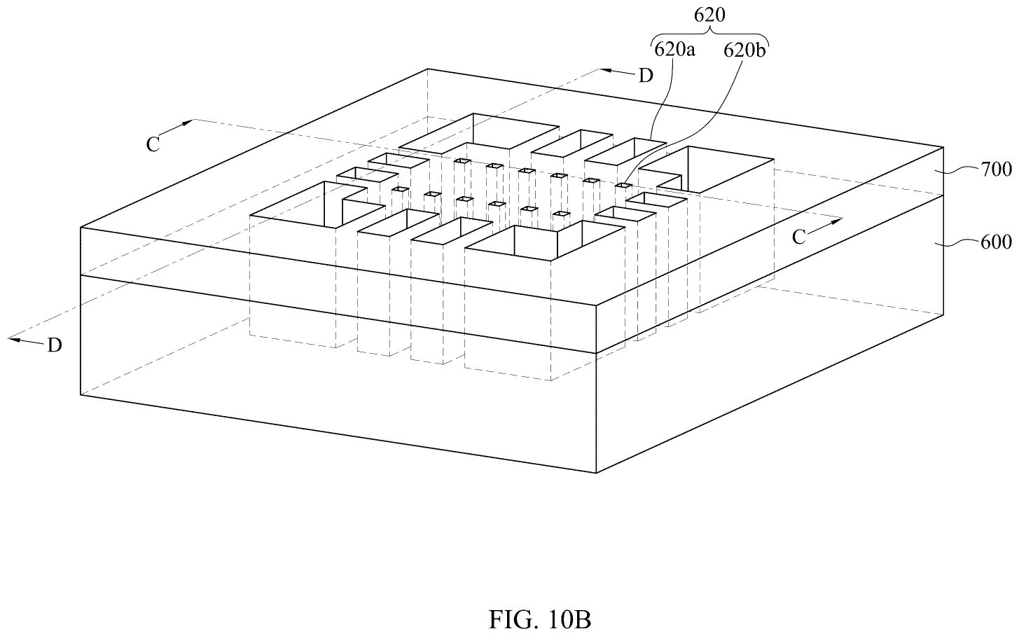

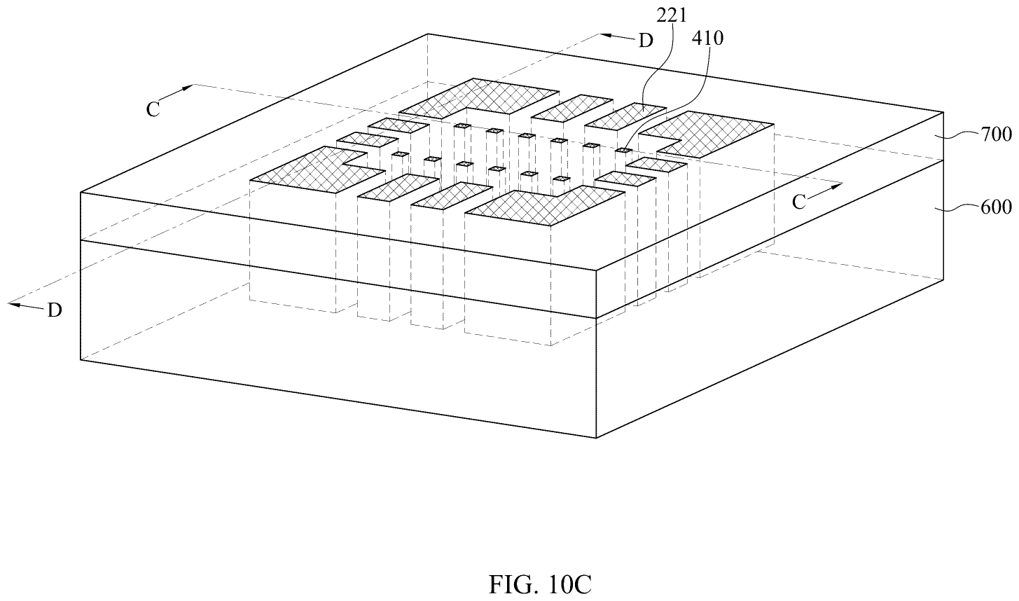

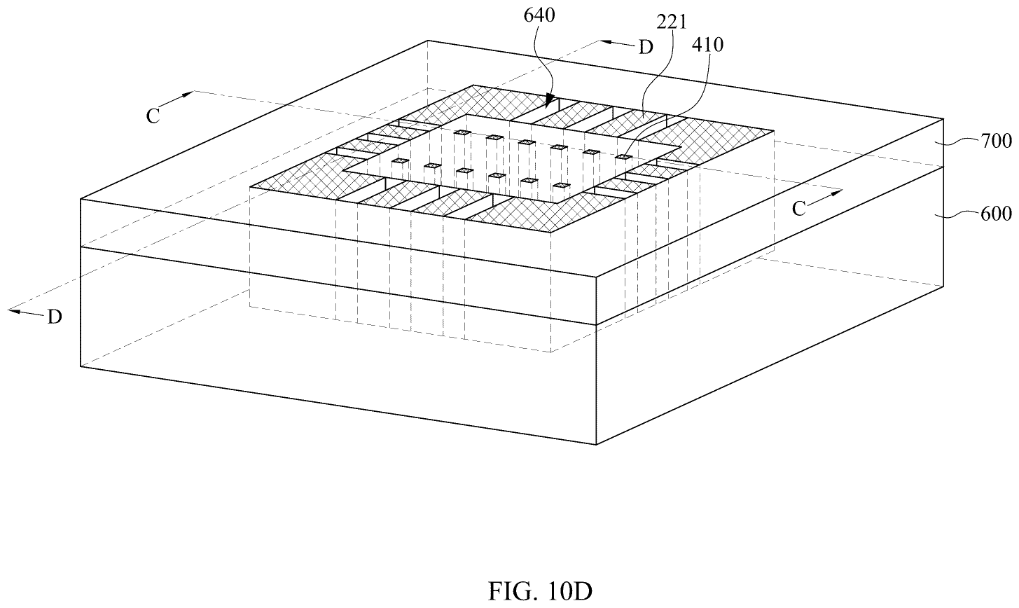

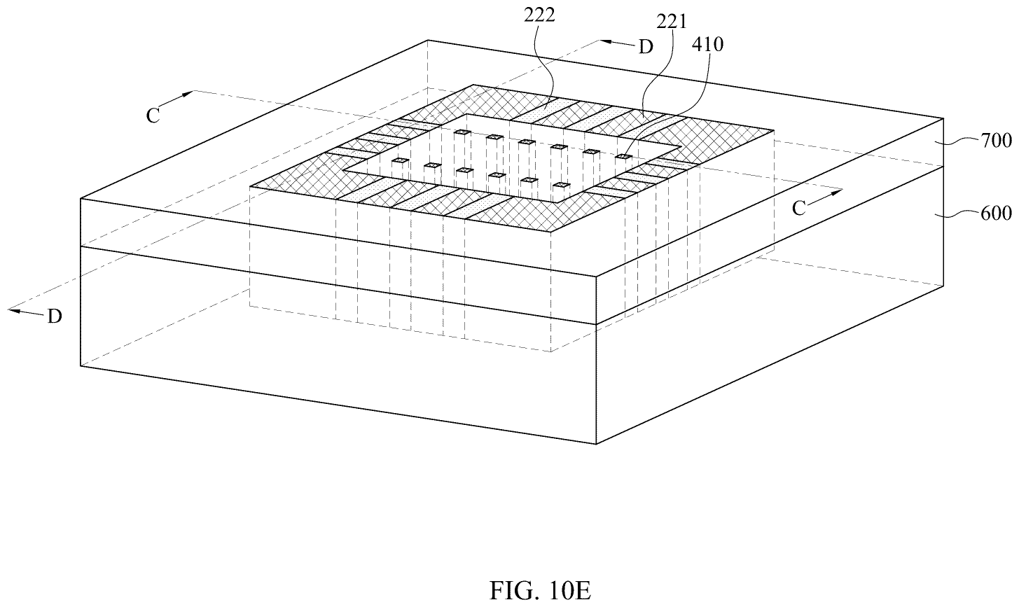

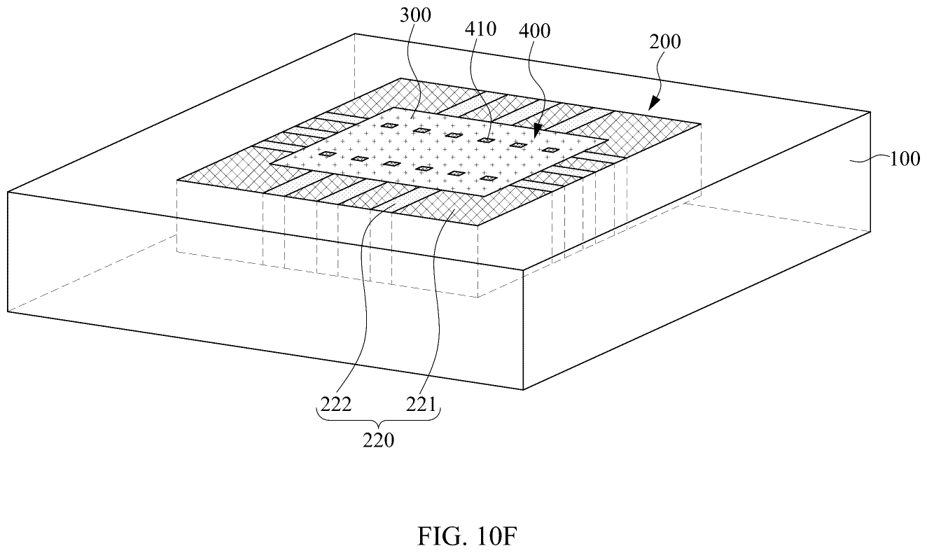

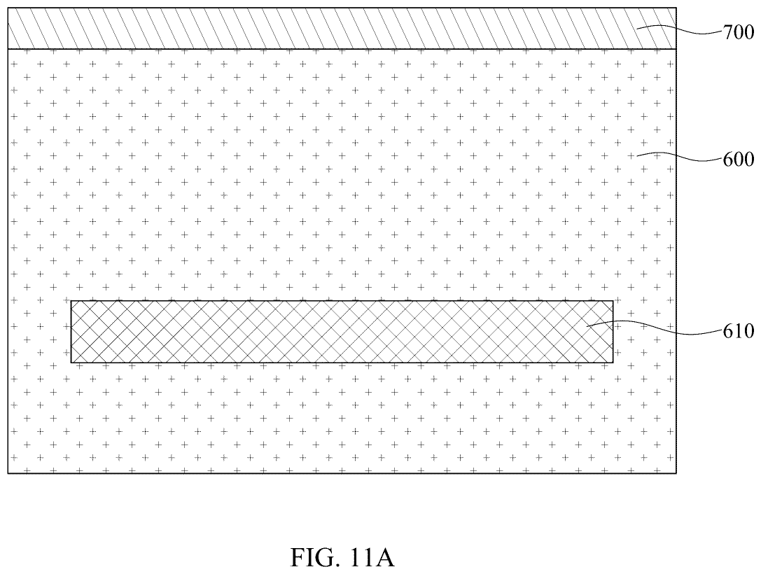

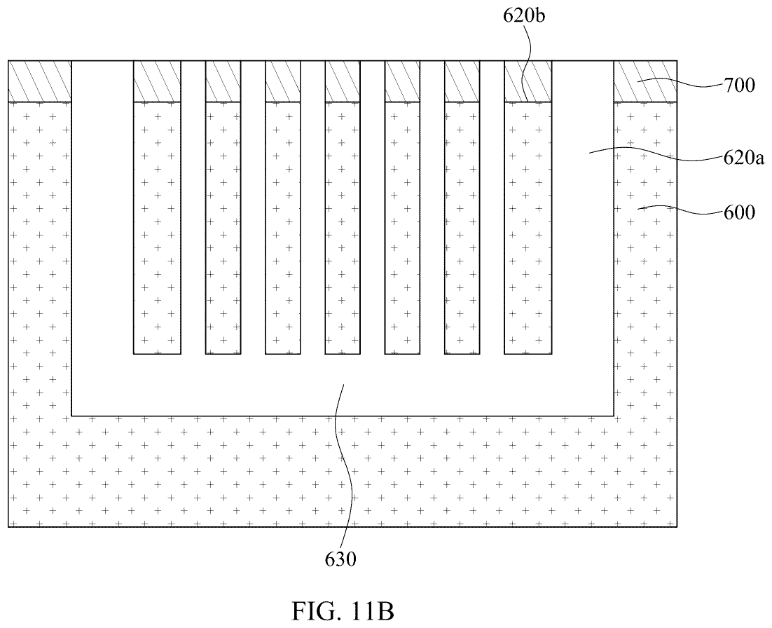

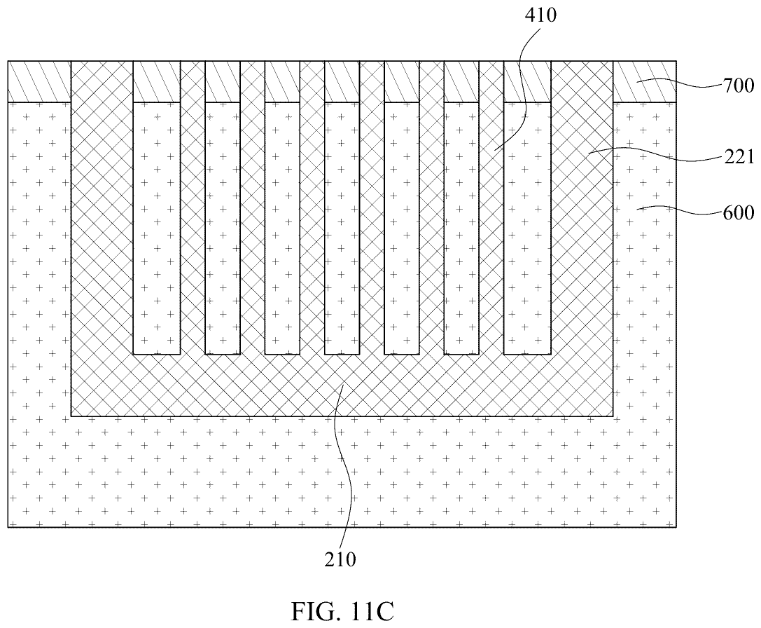

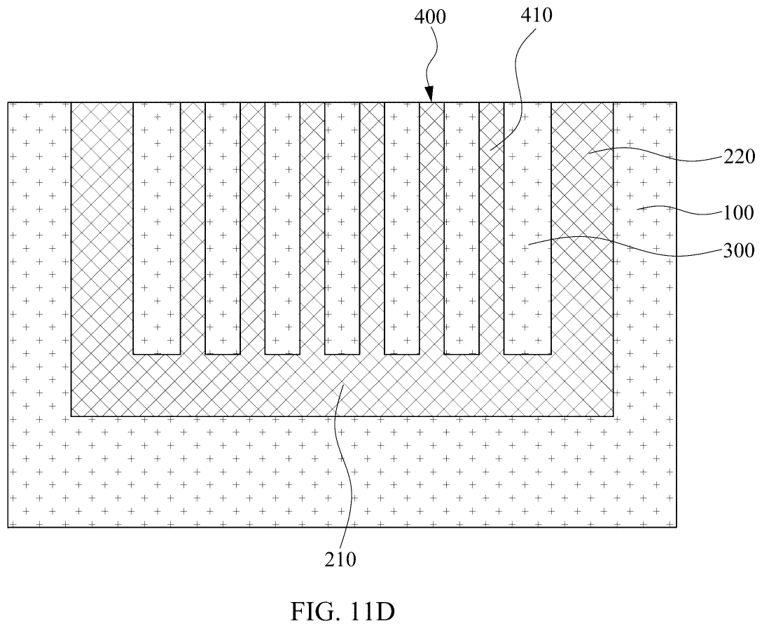

With reference to FIGS. 10A and 11A, the method 500 begins at operation 501 where an embedded doped region 610 is formed in a substrate 600 covered with a sacrificial layer 700. At operation 501, the substrate 600 is provided and received, which may be an N-type substrate or a P-type substrate; then, the sacrificial layer 700 is formed over the substrate 600 before forming the embedded doped region 610 through an implantation process. The sacrificial layer 700 may comprise nitride, silicon oxide or the like, which is used to protect the substrate 600 against any damages (such as crystal damage) generated due to the following implantation processes, so as to ensure high device performance. In some embodiments, the thickness of the sacrificial layer 700 may be from about 40 Å to about 80 Å, but the disclosure is not limited thereto. In some comparative approaches, when the thickness of the sacrificial layer 700 is less than 40 Å, it would not be thick enough to protect the substrate 600. In other comparative approaches, when the thickness of the sacrificial layer 700 is greater than 80 Å, it would be too thick to block the following implantation.

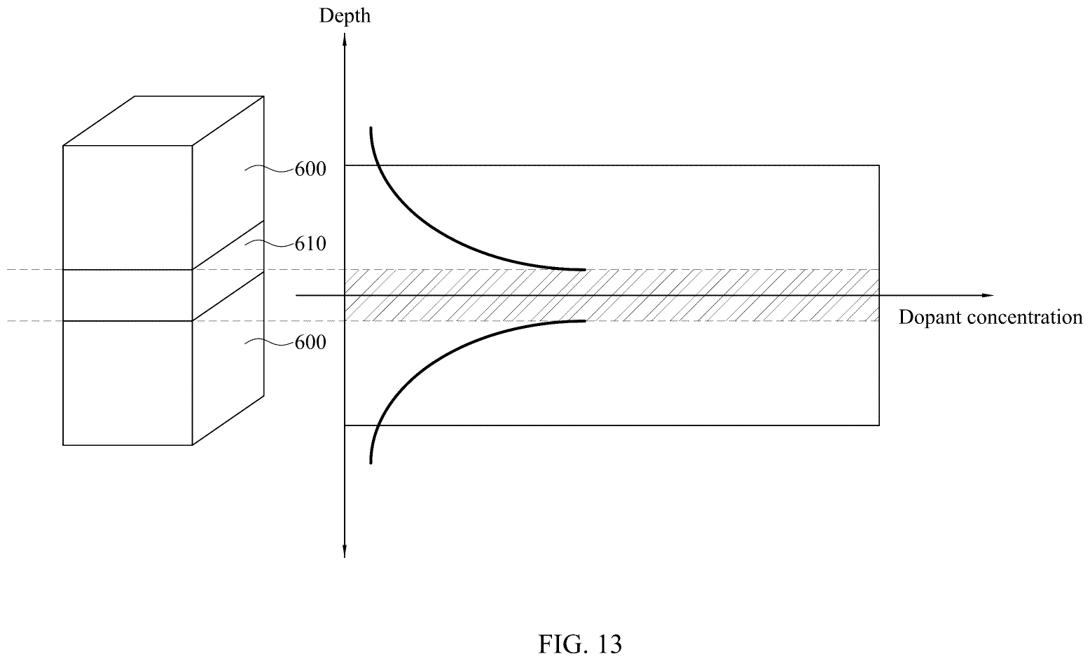

According to some embodiments, the embedded doped region 610 is formed in the substrate 600 at a predetermined depth from a top of the substrate 600 through a vertical implantation or a tilt implantation. The embedded doped region 610 formed by doping a predetermined area of the substrate 600 with dopants, so that the embedded doped region 610 has a high etching selectivity wtih respect to the substrate 600. For example, the dopants may be N-type or P-type dopant, including but not limited to B, Al, Ga, In, Ti, Nh, N, P, As, Sb, Bi or the like. The ion implantation energy, dosage, and temperature of the substrate 600 used during the implantation processes may be designed to control the penetration depth of the dopants in the substrate 600, so that the embedded doped region 610 can be formed at a predetermined depth in the substrate 600. As shown in FIG. 13, the dopants in the embedded doped region 610 may diffuse into the substrate 600, so a dopant concentration of dopants may be decreased from the embedded doped region 610 to the substrate 600 above and below the embedded doped region 610.

As shown in FIGS. 10B and 11B, the method 500 continues with operation 502 where a plurality of first trenches 620 are formed at intervals by etching the substrate 600 from the top of the substrate 600 downwardly to a depth aligned with a bottom of the embedded doped region 610; and laterally etching the embedded doped region 610 through the plurality of first trenches 620 to form a lateral tunnel 630 as shown in FIG. 11B, which communicate the plurality of first trenches 520. The plurality of first trenches 620 comprises a plurality of first peripheral trenches 620a, which are formed at intervals by etching the substrate 600 from a top of the substrate 600 downwardly to a depth aligned with a bottom of the embedded doped region 610 to connect the embedded doped region 610. The plurality of first trenches 620 may further comprise a plurality of central trenches 620b, which are formed in the substrate 600 and are surrounded by the plurality of first peripheral trenches 620a.

In some embodiments, the plurality of first trenches 620 are formed using a dry etch process, a wet etch process, or a suitable process; and the lateral tunnel 630 is formed using a dry etch process, a wet etch process, or a suitable process. For example, the plurality of first trenches 620 are formed using a dry etch process and the lateral tunnel 630 is formed using a wet etch process. Since the embedded doped region 610 comprises materials with a high etching selectivity with respect to the substrate 600, the formation of the lateral tunnel 530 can be formed in the embedded doped region 510. An example dry etch may use a fluorine-containing precursor (for example, CF₄, SF₆, NF₃, CH₂F₂, CHF₃, and/or C₂F₆), an oxygen-containing precursor, a chlorine-containing precursor (for example, Cl₂, CHCl₃, CCl₄, and/or BCl₃), a bromine-containing precursor (for example, HBr and/or CHBR₃), an iodine-containing precursor, other suitable precursor (which can be used to generate an etchant gas and/or etching plasma), or combinations thereof. An example of a wet etch process implements an etching solution that includes tetramethylammonium hydroxide (TMAH), NH₄OH, H₂O₂, H₂SO₄, HF, HCl, other suitable wet etching constituent, or combinations thereof.

The lateral etching may be even or uneven depending on the dimension of the embedded doped region 610, so a thickness of the lateral tunnel 630 may be consistent or inconsistent. For example, a thickness of the lateral tunnel 630 may be gradually decreased from an area near the first trenches 620 to a central area away from the first trenches 620. Therefore, the embedded doped region 610 may be remained in the semiconductor device of the substrate 600 near the isolation bottom 210 to be formed in the lateral tunnel 630 as shown in FIGS. 8A to 8C.

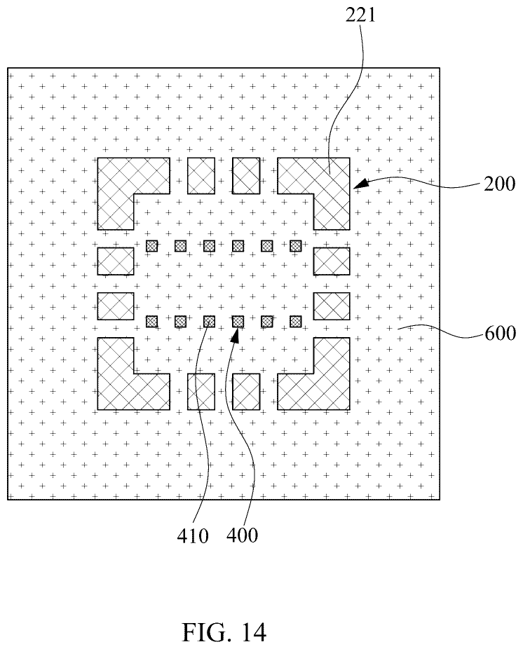

At operation 503, with further reference to FIGS. 10C, 11C and 14, the lateral tunnel 630 is filled with insulating materials to form an isolation bottom 210 and the plurality of first trenches 620 are filled with insulating materials. The plurality of first peripheral trenches 620a are filled with insulating materials to form a plurality of first insulating vias 221. The plurality of central trenches 620b are filled with insulating materials to form a via array 400 including a plurality of inner vias 410. The insulating materials include but not limited to oxide (such as SiO, doped SiO and so on), nitride (such as SiN), carbide (such as SiC), low k materials or a combination thereof. In some embodiments, the insulating materials may comprise silicon oxide, doped silicon oxide, silicon carbide, silicon nitride and so on. These are, of course, merely examples and are not intended to be limiting.

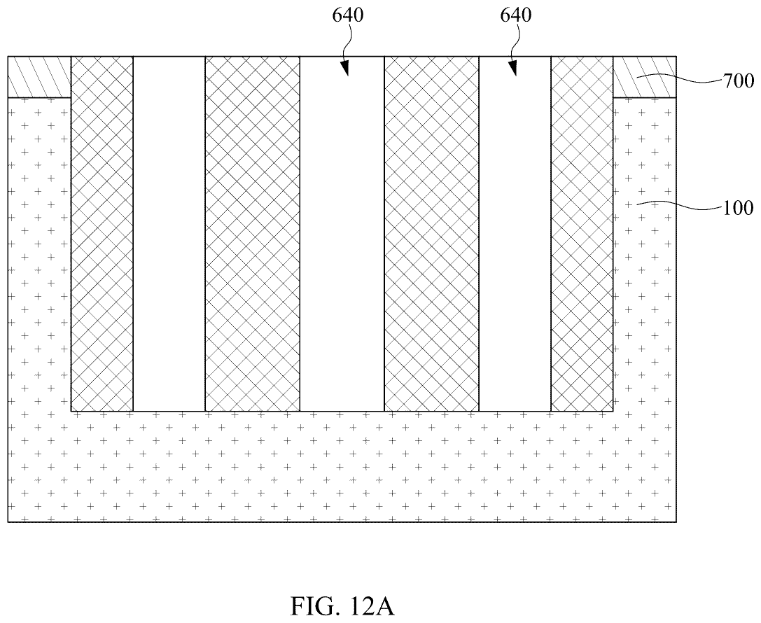

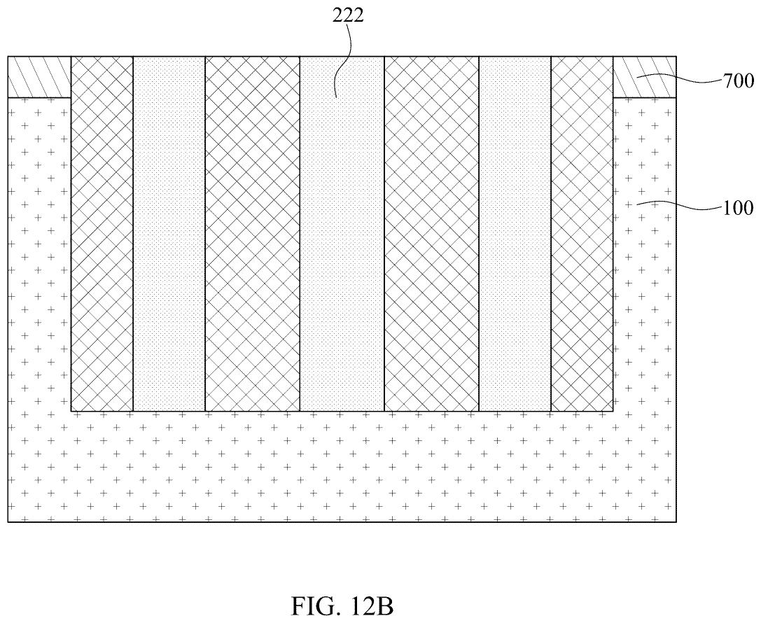

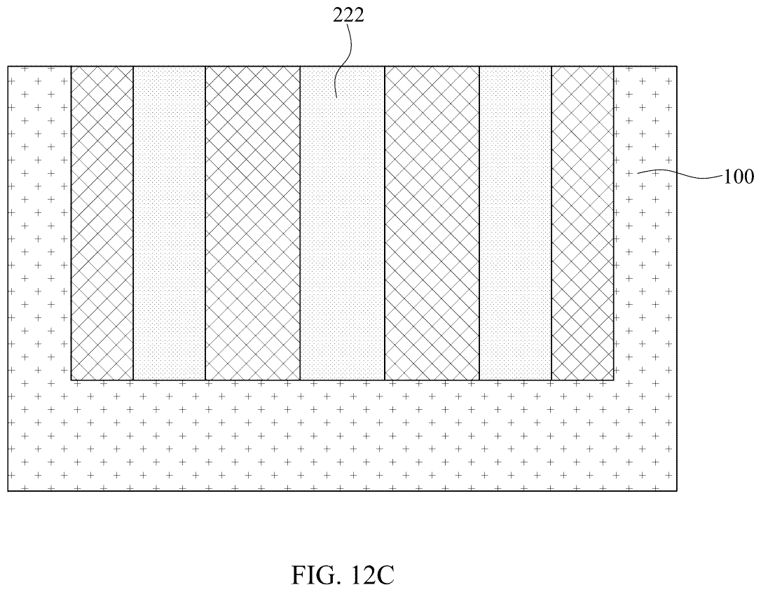

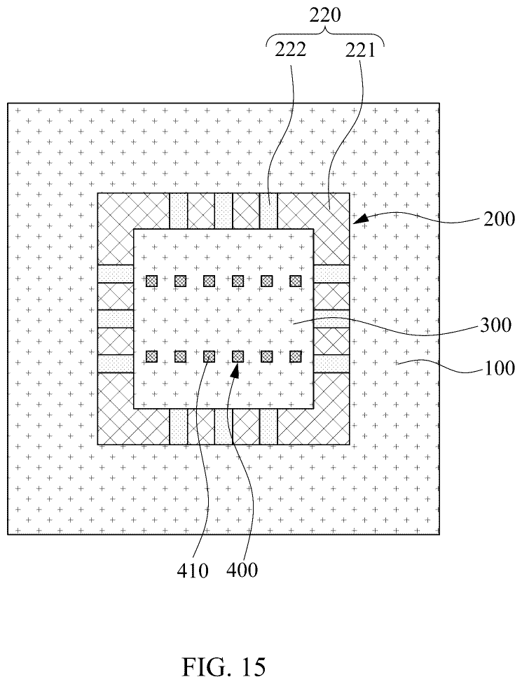

The method 500 continues with operation 504 where an isolation ring 220 are formed by etching the substrate 600 from the top of the substrate 600 downwardly to a depth aligned with a bottom of the isolation bottom 210 to form a plurality of second trenches 640; and filling the plurality of second trenches 640 with insulating materials to form a plurality of second insulating vias 222 as shown in FIGS. 10E, 12B and 15. In some embodiments, the plurality of second trenches 640 are formed between the first insulating vias 221 as shown in FIGS. 10D and 12A, so the second insulating vias 222 and the first insulating vias 221 constitute the isolation ring 220 and thus the substrate 600 is divided into a first semiconductive region 100 and a second semiconductive region 300 by the isolation structure 200 including the isolation ring 220 and the isolation bottom 210. The plurality of second trenches 640 may further comprise at least one central trench surrounded by the first insulating vias 221, which can be filled with insulating materials to form at least one inner via 410.

The second insulating vias 222 may comprise insulating materials substantially identical to the insulating materials of the first insulating vias 221 and the isolation bottom 210. The via etching and filling steps may be repeated to form more vias at different times, so that the isolation ring 220 may comprise vias with various shapes, insulating materials and so on to provide different insulating effects according to required performance as shown in FIGS. 6 and 7.

Before conducting following procedures, the sacrificial layer 700 can be removed as shown in FIGS. 10E, 11D and 12C to expose a top of the first semiconductive region 100, a top of the second semiconductive region 300, a top of the isolation ring 220 and a top of the via array 400.

The formation of the via array 400 provides improved lateral etching uniformity, so the isolation structure 200 of the present disclosure may be applied to various design, in particular a large circuit, which offers design flexibility. The isolation structure 200 provides a better isolation on full direction and less parasitic effect and the semiconductor device of the present disclosure may operate under an operation voltage from about 0.1V to about 1000V.

In some embodiments, a semiconductor device of the present disclosure comprises a first semiconductive region; a second semiconductive region; an isolation structure formed between the first semiconductive region and the second semiconductive region and comprising: an isolation bottom formed beneath the second semiconductive region; and an isolation ring having a lower portion connecting the isolation bottom and an upper portion surrounding the second semiconductive region; and at least one inner via formed in the second semiconductive region, on the isolation bottom and surrounded by the isolation structure, wherein the isolation structure and the least one inner via have insulating materials.

In some embodiments, a semiconductor device comprises a first semiconductive region; a second semiconductive region; and an isolation structure formed between the first semiconductive region and the second semiconductive region and comprising: an isolation bottom formed beneath the second semiconductive region; and an isolation ring having a lower portion connecting the isolation bottom and an upper portion surrounding the second semiconductive region; a via array comprising a plurality of inner via formed in the second semiconductive region, on the isolation bottom and surrounded by the isolation structure, wherein the isolation structure and the plurality of inner vias have insulating materials, and wherein each of the plurality of inner via has a top and a bottom and an area of the top is larger than that of the bottom.

In some embodiments, a method for forming a semiconductor device of the present disclosure comprises forming an embedded doped region in a substrate; and forming an isolation ring and at least one inner via in the substrate; wherein forming the isolation ring comprises: forming a plurality of first insulating vias and an isolation bottom by etching a plurality of first trenches and a lateral tunnel in the substrate; and filling the plurality of first trenches and the lateral tunnel with insulating materials; and forming a plurality of second insulating vias by etching a plurality of second trenches in the substrate between the plurality of first insulating vias; and filling the plurality of second trenches with insulating materials, wherein the isolation ring and the isolation bottom separating the substrate into a first semiconductive region and a second semiconductive region, and wherein the second semiconductive region is surrounded by the isolation ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor device, comprising:
a first semiconductive region;
a second semiconductive region;
an isolation structure formed between the first semiconductive region and the second semiconductive region and comprising:
an isolation bottom formed beneath the second semiconductive region; and
an isolation ring having a lower portion connecting the isolation bottom and an upper portion surrounding the second semiconductive region; and
at least one inner via formed in the second semiconductive region, on the isolation bottom and surrounded by the isolation structure,
wherein the isolation structure and the least one inner via have insulating materials.

2. The semiconductor device of claim 1, wherein the isolation ring has a substantially flat or serrated inner surface and a substantially flat or serrated outer surface from a top view.

3. The semiconductor device of claim 1, wherein the isolation ring comprises a plurality of first insulating vias and a plurality of second insulating vias formed alternately, and wherein an area of a top of each of the plurality of first insulating vias is different from that of each of the plurality of second insulating via.

4. The semiconductor device of claim 1, wherein the isolation ring comprises a plurality of first insulating vias and a plurality of second insulating via formed alternately, and wherein the plurality of first insulating vias comprise an insulating material that is different from an insulating material of the plurality of second insulating via.

5. The semiconductor device of claim 1, wherein the isolation structure further comprises at least one embedded doped region abutting the isolation bottom; and wherein the at least one embedded doped region comprises materials with a high etching selectivity with respect to the first semiconductive region and the second semiconductive region.

6. The semiconductor device of claim 1, wherein a thickness of the isolation bottom is decreased from an area near the at least one inner via and the isolation ring to an area away from the inner vias and the isolation ring.

7. The semiconductor device of claim 1, wherein a top of the first semiconductive region, a top of the second semiconductive region, and a top of the isolation structure are substantially coplanar with each other.

8. A semiconductor device, comprising:
a first semiconductive region;
a second semiconductive region;
an isolation structure formed between the first semiconductive region and the second semiconductive region and comprising:
an isolation bottom formed beneath the second semiconductive region; and
an isolation ring having a lower portion connecting the isolation bottom and an upper portion surrounding the second semiconductive region; and
a via array comprising a plurality of inner via formed in the second semiconductive region, on the isolation bottom and surrounded by the isolation structure,
wherein the isolation structure and the plurality of inner vias have insulating materials, and
wherein each of the plurality of inner via has a top and a bottom and an area of the top is larger than that of the bottom.

9. The semiconductor device of claim 8, wherein the via array comprises a plurality of first inner vias and a plurality of second insulating vias, and wherein an area of the top of each of the plurality of first inner vias is different from that of each of the plurality of second inner via.

10. The semiconductor device of claim 8, wherein the via array comprises a plurality of first inner vias and a plurality of second insulating vias, and wherein each of the plurality of first inner vias has a top cross section, which is different in shape from that of each of the plurality of second inner via.

11. The semiconductor device of claim 8, wherein the via array comprises a plurality of first inner vias and a plurality of second inner vias, and wherein the plurality of first inner vias comprise an insulating material that is different from an insulating material of the plurality of second inner via.

12. The semiconductor device of claim 8, wherein the isolation structure and the plurality of inner vias have substantially identical insulating materials.

13. The semiconductor device of claim 8, wherein a thickness of the isolation bottom is consistent from an area near the plurality of inner via and the isolation ring to an area away from the plurality of inner via and the isolation ring.

14. The semiconductor device of claim 8, wherein the isolation ring comprises a plurality of first insulating vias and a plurality of second insulating vias formed alternately.

15. A method for manufacturing a semiconductor device, comprising:
forming an embedded doped region in a substrate; and
forming an isolation ring and at least one inner via in the substrate,
wherein forming the isolation ring comprises:
forming a plurality of first insulating vias and an isolation bottom by etching a plurality of first trenches and a lateral tunnel in the substrate; and filling the plurality of first trenches and the lateral tunnel with insulating materials; and
forming a plurality of second insulating vias by etching a plurality of second trenches in the substrate between the plurality of first insulating vias; and filling the plurality of second trenches with insulating materials,
wherein the isolation ring and the isolation bottom separating the substrate into a first semiconductive region and a second semiconductive region, and
wherein the second semiconductive region is surrounded by the isolation ring.

16. The method of claim 15, wherein the at least one inner via is formed during a formation of the plurality of first insulating vias.

17. The method of claim 15, wherein the at least one inner via is formed during a formation of the plurality of second insulating vias.

18. The method of claim 15, wherein forming the at least one inner via comprises etching a plurality of third trenches in the substrate surrounded by the plurality of first insulating vias; and filling the plurality of third trenches with insulating materials.

19. The method of claim 15, wherein the plurality of first trenches and the plurality of second trenches are formed by dry etching the substrate and the lateral tunnel is formed by wet etching the embedded doped region.

20. The method of claim 15, wherein the embedded doped region has a high etching selectivity in respect to the substrate.
